(19) United States
(12) Patent Application Publication
(10) Pub. No.: US 2026/0047041 A1
(43) Pub. Date: Feb. 12, 2026

(54) Parallel Flow Liquid Cooling Distribution Assembly With Piston Like Pluggable Optical Module Riding Cold Plates

(71) Applicant: Ciena Corporation, Hanover, MD (US)

(72) Inventors: Simon Shearman, Carleton Place (CA); Behzad Mohajer, Burnaby (CA)

(21) Appl. No.: 18/796,458

(22) Filed: Aug. 7, 2024

(51) Int. Cl. H05K 7/20

(52) U.S. Cl. CPC H05K 7/20272; H05K 7/20254

(57) ABSTRACT

A parallel flow liquid cooling distribution assembly for use in a telecommunications or optical networking system, the assembly including: a fluid distribution plenum defining an inlet plenum and an outlet plenum; and a plurality of cold plates coupled to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated pluggable optical module through an associated cage of a plurality of cages and pluggable optical modules.

### TECHNICAL FIELD

The present disclosure relates generally to the telecommunications and optical networking fields. More particularly, the present disclosure relates to a parallel flow liquid cooling distribution assembly with piston like pluggable optical module (POM) riding cold plates.

### BACKGROUND

POMs disposed within cages in a box mounted in a rack of a telecommunications or optical networking system are often cooled with riding cold plates that contact the POMs through the cages. Each of the cold plates typically utilizes a cool liquid inlet tube and a hot liquid outlet tube, with all of the tubes typically coupled to one or more fluid distribution plenums that are disposed behind the cages. Each of the cold plates is typically biased towards the associated POM.

These liquid cooling distribution assemblies are often suboptimal and have a relatively large form factor, often blocking air flow through a faceplate of the box and across the nose of each of the POMs and the cages. Further, the liquid cooling distribution assemblies often provide complex and unreliable fluid connections.

The present background is provided as environmental context only. It will be readily apparent to those of ordinary skill in the art that the principles and concepts of the present disclosure may be implemented in other environmental contexts equally, without limitation.

### SUMMARY

The present disclosure provides a parallel flow liquid cooling distribution assembly with piston like POM riding cold plates. This liquid cooling distribution assembly is optimal and has a relatively small form factor, promoting air flow through the faceplate of the box and across the nose of each of the POMs and the cages. Further, the liquid cooling distribution assembly provides simple and reliable fluid connections. The cold plates utilize a common cool liquid inlet tube and a common hot liquid outlet tube coupled to a fluid distribution plenum that is disposed adjacent to (i.e., above or below) or behind the cages. Each of the cold plates is biased towards the associated POM via a novel piston like mechanism. The parallel flow liquid cooling distribution assembly of the present disclosure may be used with individual or ganged cages in one side or two side configurations.

In some embodiments, the present disclosure provides a parallel flow liquid cooling distribution assembly for use in a telecommunications or optical networking system, the assembly including: a fluid distribution plenum defining an inlet plenum and an outlet plenum; and a plurality of cold plates coupled to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated pluggable optical module through an associated cage of a plurality of cages and pluggable optical modules. The O-rings are each retained within a groove formed in one or both of the inlet piston cylinder or the outlet piston cylinder and the inlet port or the outlet port. In some embodiments, the fluid distribution plenum is disposed adjacent to (i.e., above or below) the plurality of cages and pluggable optical modules, with the plurality of cold plates disposed between the fluid distribution plenum and the plurality of cages and pluggable optical modules. This assembly further includes a spring disposed between each of the cold plates and the fluid distribution plenum, where the spring is adapted to bias each of the cold plates away from the fluid distribution plenum and into the surface of the associated pluggable optical module. In some embodiments, each of the cold plates is disposed partially within an associated conformal recess formed in the fluid distribution plenum. In some embodiments, the fluid distribution plenum includes a retention plate that is disposed about the plurality of cold plates and coupled to the fluid distribution plenum to retain a lip structure of each of the cold plates within the associated conformal recess to couple the plurality of cold plates to the fluid distribution plenum such that each of the plurality of cold plates may be translated or biased towards or away from the fluid distribution plenum. In some embodiments, the fluid distribution plenum is disposed behind the plurality of cages and pluggable optical modules, with the plurality of cold plates extending from the fluid distribution plenum to be disposed adjacent to plurality of cages and pluggable optical modules. In this assembly, the inlet piston cylinder and the outlet piston cylinder are disposed at an end of each of the cold plates. In some embodiments, this assembly further includes a retention member that traverses the end of each of the cold plates and is secured to the fluid distribution plenum to secure the plurality of cold plates to the fluid distribution plenum. In some embodiments, this assembly further includes a clip member that traverses each of the cold plates and is secured to the associated cage to bias each of the cold plates into the surface of the associated pluggable optical module. In some embodiments, this assembly further includes a retention plate that is disposed along the end of each of the cold plates and is secured to the fluid distribution plenum to secure the plurality of cold plates to the fluid distribution plenum, where the retention plate defines a plurality of slots adapted to receive associated tabs provided at the ends of the cold plates. In some embodiments, each of the plurality of slots has a height that is larger than a height of the associated tab, such that each of the plurality of cold plates is provided with a degree to translation with respect to the fluid distribution plenum. In some embodiments, the retention plate defines a plurality of cutouts between adjacent cold plates of the plurality of cold plates that allow air flow past the plurality of cages and pluggable optical modules and the fluid distribution plenum. In some embodiments, each of the cold plates includes a body having a first planar portion proximate to the fluid distribution plenum, a second planar portion distal to the fluid distribution plenum, and a ramped transition portion disposed between the first planar portion and the second planar portion. In some embodiments, each of the cold plates has a tapering thickness, being relatively thicker in height proximate to the fluid distribution plenum and relatively thinner in height distal to the fluid distribution plenum. In some embodiments, each of the cold plates includes an external pad adapted to make contact with the surface of the associated pluggable optical module through the associated cage.

In some embodiments, the present disclosure provides a telecommunications or optical networking box assembly, including: a case; a printed circuit board disposed within the case; a plurality of cages disposed on a first side of the printed circuit board and adapted to receive a plurality of pluggable optical modules on the first side of the printed circuit board; a fluid distribution plenum defining an inlet plenum and an outlet plenum disposed on the first side of the printed circuit board; and a plurality of cold plates coupled to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated pluggable optical module through an associated cage of the plurality of cages and pluggable optical modules disposed on the first side of the printed circuit board. In some embodiments, the assembly further includes: a plurality of cages disposed on a second side of the printed circuit board and adapted to receive a plurality of pluggable optical modules on the second side of the printed circuit board; a fluid distribution plenum defining an inlet plenum and an outlet plenum disposed on the second side of the printed circuit board; and a plurality of cold plates coupled to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated pluggable optical module through an associated cage of the plurality of cages and pluggable optical modules disposed on the second side of the printed circuit board.

In some embodiments, the present disclosure provides a telecommunications or optical networking method, including: providing a case; providing a printed circuit board disposed within the case; providing a plurality of cages disposed on a first side of the printed circuit board and adapted to receive a plurality of pluggable optical modules on the first side of the printed circuit board; disposing a fluid distribution plenum defining an inlet plenum and an outlet plenum on the first side of the printed circuit board; and coupling a plurality of cold plates to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated pluggable optical module through an associated cage of the plurality of cages and pluggable optical modules disposed on the first side of the printed circuit board. In some embodiments, the method further includes: providing a plurality of cages disposed on a second side of the printed circuit board and adapted to receive a plurality of pluggable optical modules on the second side of the printed circuit board; disposing a fluid distribution plenum defining an inlet plenum and an outlet plenum on the second side of the printed circuit board; and coupling a plurality of cold plates to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated pluggable optical module through an associated cage of the plurality of cages and pluggable optical modules disposed on the second side of the printed circuit board.

It will be readily apparent to those of ordinary skill in the art that aspects and features of each of the described embodiments may be incorporated, omitted, and/or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 illustrates a typical liquid cooling distribution assembly;

FIG. 2 illustrates an embodiment of the parallel flow liquid cooling distribution assembly of the present disclosure;

FIG. 3 further illustrates the parallel flow liquid cooling distribution assembly of FIG. 2;

FIG. 4 further illustrates the parallel flow liquid cooling distribution assembly of FIG. 2, highlighting the associated piston cold plate mechanism;

FIG. 5 further illustrates the parallel flow liquid cooling distribution assembly of FIG. 2;

FIG. 6 further illustrates the parallel flow liquid cooling distribution assembly of FIG. 2;

FIG. 7 further illustrates the parallel flow liquid cooling distribution assembly of FIG. 2;

FIG. 8 further illustrates the parallel flow liquid cooling distribution assembly of FIG. 2, highlighting the positioning of the parallel flow liquid cooling distribution assembly in a box;

FIG. 9 further illustrates the parallel flow liquid cooling distribution assembly of FIG. 2, highlighting a two side configuration;

FIG. 10 illustrates another embodiment of the parallel flow liquid cooling distribution assembly of the present disclosure;

FIG. 11 further illustrates the parallel flow liquid cooling distribution assembly of FIG. 10;

FIG. 12 further illustrates the parallel flow liquid cooling distribution assembly of FIG. 10;

FIG. 13 further illustrates the parallel flow liquid cooling distribution assembly of FIG. 10;

FIG. 14 further illustrates the parallel flow liquid cooling distribution assembly of FIG. 10;

FIG. 15 illustrates a further embodiment of the parallel flow liquid cooling distribution assembly of the present disclosure;

FIG. 16 further illustrates the parallel flow liquid cooling distribution assembly of FIG. 15;

FIG. 17 further illustrates the parallel flow liquid cooling distribution assembly of FIG. 15;

FIG. 18 further illustrates the parallel flow liquid cooling distribution assembly of FIG. 15;

FIG. 19 illustrates a further embodiment of the parallel flow liquid cooling distribution assembly of the present disclosure, similar to FIGS. 15-18;

FIG. 20 further illustrates the parallel flow liquid cooling distribution assembly of FIG. 19, similar to FIGS. 15-18;

FIG. 21 further illustrates the parallel flow liquid cooling distribution assembly of FIG. 19, highlighting the positioning of the parallel flow liquid cooling distribution assembly in a box, similar to FIGS. 15-18;

FIG. 22 further illustrates the parallel flow liquid cooling distribution assembly of FIG. 19, highlighting a one side configuration, similar to FIGS. 15-18;

FIG. 23 illustrates a further embodiment of the parallel flow liquid cooling distribution assembly of the present disclosure, similar to FIG. 15 except for the inlet and outlet tube locations;

FIG. 24 further illustrates the parallel flow liquid cooling distribution assembly of FIG. 23, similar to FIG. 15 except for the inlet and outlet tube locations;

FIG. 25 further illustrates the parallel flow liquid cooling distribution assembly of FIG. 23, similar to FIG. 15 except for the inlet and outlet tube locations;

FIG. 26 further illustrates the parallel flow liquid cooling distribution assembly of FIG. 23, similar to FIG. 15 except for the inlet and outlet tube locations;

FIG. 27 illustrates a further embodiment of the parallel flow liquid cooling distribution assembly of the present disclosure, similar to FIG. 15 except for the inlet and outlet tube locations;

FIG. 28 further illustrates the parallel flow liquid cooling distribution assembly of FIG. 27, similar to FIG. 15 except for the inlet and outlet tube locations;

FIG. 29 illustrates a further embodiment of the parallel flow liquid cooling distribution assembly of the present disclosure;

FIG. 30 further illustrates the parallel flow liquid cooling distribution assembly of FIG. 29;

FIG. 31 further illustrates the parallel flow liquid cooling distribution assembly of FIG. 29;

FIG. 32 further illustrates the parallel flow liquid cooling distribution assembly of FIG. 29;

FIG. 33 further illustrates the parallel flow liquid cooling distribution assembly of FIG. 29;

FIG. 34 further illustrates the parallel flow liquid cooling distribution assembly of FIG. 29; and

FIG. 35 illustrates an embodiment of the parallel flow liquid cooling distribution method of the present disclosure.

It will be readily apparent to those of ordinary skill in the art that aspects and features of each of the illustrated embodiments may be incorporated, omitted, and/or combined as desired in a given application, without limitation.

### DETAILED DESCRIPTION

Again, the present disclosure provides a parallel flow liquid cooling distribution assembly with piston like POM riding cold plates. This liquid cooling distribution assembly is optimal and has a relatively small form factor, promoting air flow through the faceplate of the box and across the nose of each of the POMs and the cages. Further, the liquid cooling distribution assembly provides simple and reliable fluid connections. The cold plates utilize a common cool liquid inlet tube and a common hot liquid outlet tube coupled to a fluid distribution plenum that is disposed adjacent to (i.e., above or below) or behind the cages. Each of the cold plates is biased towards the associated POM via a novel piston like mechanism. The parallel flow liquid cooling distribution assembly of the present disclosure may be used with individual or ganged cages in one side or two side configurations.

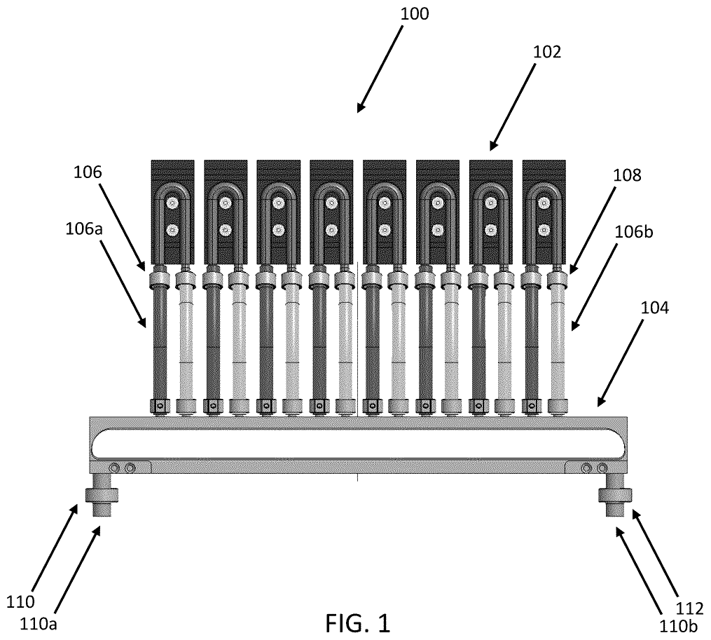

FIG. 1 illustrates a typical liquid cooling distribution assembly 100 that includes a plurality of individual cold plates 102 each coupled to a fluid distribution plenum 104 by an individual cool liquid inlet tube 106a and a hot liquid outlet tube 106b. The fluid distribution plenum 104 may consist of a single integrated structure that encompasses both cool liquid inlet and hot liquid outlet paths, or the fluid distribution plenum 104 may consist of multiple structures that individually encompass cool liquid inlet and hot liquid outlet paths. The former may occupy less space, while the latter may occupy more space. The fluid distribution plenum 104 is typically disposed behind the POMs and cages disposed on the printed circuit board (PCB) of the associated box. Eight (8) cold plates 102 are illustrated for eight (8) individual POMs and cages. Sixteen (16) tubes 106 are required for the eight (8) cold plates, as well as thirty-two (32) connection clamps 108 for the sixteen (16) tubes 106. A cool liquid inlet tube 110a and hot liquid outlet tube 110b are also coupled to the fluid distribution plenum 104 with connection clamps 112 as the primary inlet and outlet. This assembly of tubes 106,206 and clamps 108,112 takes up significant space and may lead to complex and unreliable fluid connections, which must be manually made.

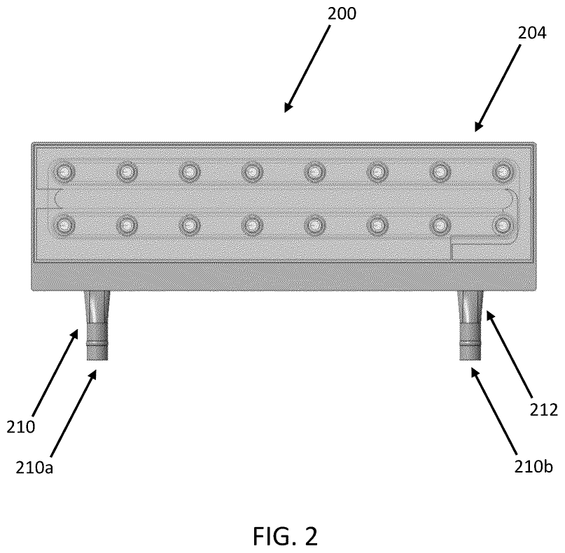

FIG. 2 illustrates an embodiment of the parallel flow liquid cooling distribution assembly 200 of the present disclosure. Here, the liquid cooling distribution assembly 200 utilizes an integrated plenum 204 that is disposed adjacent to (i.e., above or below) the POMs and cages disposed on the PCB of the associated box. Only two (2) tubes 210, a cool liquid inlet tube 210a and hot liquid outlet tube 210b are coupled to the fluid distribution plenum 204 with connection clamps or fittings 212 to feed any number of cold plates, which are coupled to the fluid distribution plenum 204 by the mechanism described in greater detail. This assembly of tubes 210 and clamps or fittings 212 takes up significantly less space and eliminates many complex and unreliable fluid connections.

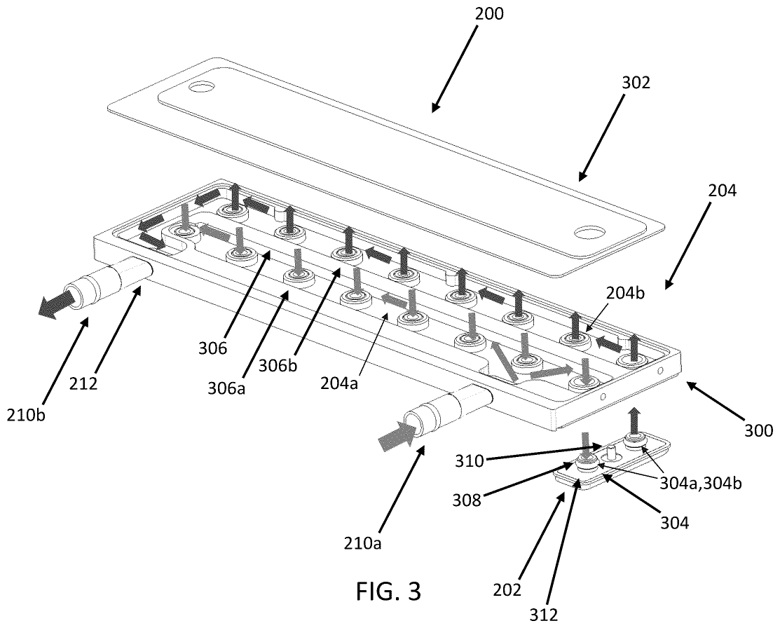

FIG. 3 further illustrates the parallel flow liquid cooling distribution assembly 200 of FIG. 2. The fluid distribution plenum 204 includes an inlet plenum 204a and an outlet plenum 204b integrated into a single structure including a body 300 and an affixed, sealed lid 302. The body 300 and lid 302 may be made of any suitable rigid material, such as a metallic or plastic material. The inlet tube 210a is in fluid communication with the inlet plenum 204a and the outlet tube 210b is in fluid communication with the outlet plenum 204b, forming a continuous fluid flow path from the inlet tube 210a, through the inlet plenum 204a, through each of the cold plates 202 in parallel, through the outlet plenum 204b, and to the outlet tube 210b, forming a cooling fluid path with the cold plates 202 disposed in parallel. Each of the cold plates 202, of which any number may be used and associated with any number of cages and POMS, whether individual or ganged, is fluidly coupled to the fluid distribution plenum 204 via an inlet piston cylinder 304a and an outlet piston cylinder 304b, each of which is disposed within a corresponding inlet/outlet port 306a,306b of the fluid distribution plenum 204. O-rings 308 are provided around the piston cylinders 304 to provide a sealing connection that allows relative translation of each of the cold plates 202 with respect to the fluid distribution plenum 204. A spring peg 310 is also provided on the cold plate lid 312 around which a spring is disposed, thereby biasing the cold plates 202 away from the fluid distribution plenum 204 and into the associated POMs when everything is assembled together.

The O-rings 308 are a common mechanism to allow a joint to be sealed but enable a degree of translational and/or rotational movement. The O-rings 308 are sized to compress into a tightly toleranced groove in a cylinder disposed within a port, for example, allowing fluid to pass through the cylinder and port, and the O-ring 308 itself, while the cylinder and port are sealed with respect to each other by the O-ring 308.

The piston arrangement of the present disclosure allows the cooling fluid to be circulated from the fluid distribution plenum 204 through the cold plates 202 in parallel, while the cold plates 202 are biased away from the fluid distribution plenum 204 into the contacted POMs in a height restricted fluid containment application. This parallel cold plate configuration means that the same degree of cooling can be provided to each POM, as the POMs are not cooled in series, which would result in the first cold plate 202 providing the greatest degree of cooling and the last cold plate 202 providing the smallest degree of cooling as the cooling fluid is heated along the series. In the parallel cold plate configuration, each cold plate 202 receives the same cool liquid from the inlet tube 210a and the inlet plenum 204a in parallel and provides hot liquid to the outlet plenum 204b for communication directly to the outlet tube 210b.

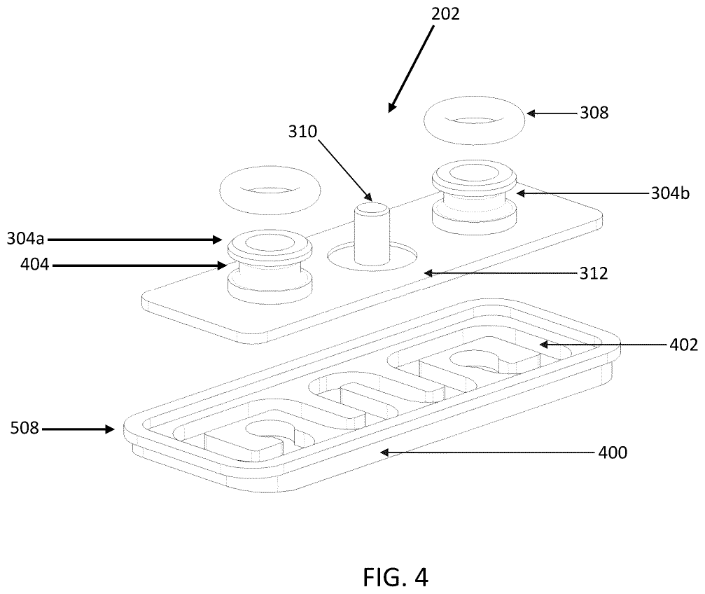

FIG. 4 further illustrates the parallel flow liquid cooling distribution assembly 200 of FIG. 2, highlighting the associated piston cold plate mechanism. Each cold plate 202 includes a body 400 that defines a fluid flow path 402 from the inlet piston cylinder 304a to the outlet piston cylinder 304b. The fluid flow path 402 may be linear, circuitous, and/or could consist of a channel or chamber interrupted by fin structures or the like, well known to those of ordinary skill in the art with respect to such cold plate structures. The body 400 is sealingly enclosed by the cold plate lid 312, to/through which the inlet piston cylinder 304a and the outlet piston cylinder 304b are attached, as well as the spring peg 310. Each piston cylinder 304a,304b includes an external circumferential O-ring groove 404 in which one of the O-rings 308 is disposed. It should be noted that the body 400 of each cold plate 202 may include tapered, rounded, and/or ramped external surfaces that assist insertion/removal of the associated POM into the associated cage with the cold plate 202 making contact with the surface of the POM. The body 400 and cold plate lid 312 may be made of any suitable rigid material, such as a metallic material.

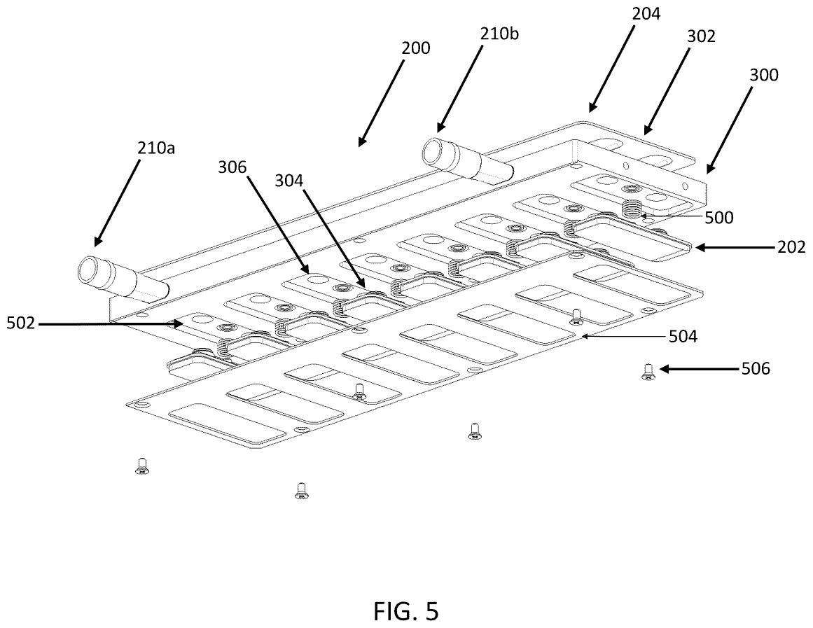

FIG. 5 further illustrates the parallel flow liquid cooling distribution assembly 200 of FIG. 2. Again, the fluid distribution plenum 204 includes the inlet plenum 204a and the outlet plenum 204b integrated into the single structure including the body 300 and the affixed, sealed lid 302. The inlet tube 210a is in fluid communication with the inlet plenum 204a and the outlet tube 210b is in fluid communication with the outlet plenum 204b, forming the continuous fluid flow path from the inlet tube 210a, through the inlet plenum 204a, through each of the cold plates 202 in parallel, through the outlet plenum 204b, and to the outlet tube 210b. Each of the cold plates 202, of which any number may be used and associated with any number of cages and POMS, is fluidly coupled to the fluid distribution plenum 204 via the inlet piston cylinder 304a and the outlet piston cylinder 304b, each of which is disposed within the corresponding port 306a,306b of the fluid distribution plenum 204. The O-rings 308 are provided around the piston cylinders 304 to provide the sealing connection that allows relative translation of each of the cold plates 202 with respect to the fluid distribution plenum 204. The spring peg 310 is also provided on the cold plate lid 312 around which the spring 500 is disposed, thereby biasing the cold plates 202 away from the fluid distribution plenum 204 and into the associated POMs. Each of the cold plates 202 sits partially within a conformal recess 502 formed in the body 300 of the fluid distribution plenum 204, and the cold plates 202 are surrounded and retained by a retaining plate 504 secured to the body 300 opposite the lid 302 via screws 506 or the like, such that the cold plates 202 are depressibly secured to the body 300 of the fluid distribution plenum 204. This securement is accomplished via a lip structure 508 that is disposed around a base perimeter of each of the cold plates 202 (see FIG. 4) and caught or limited by the retaining plate 504. The retaining plate 504 compresses the springs 500 disposed around the spring pegs 310 and serving to bias the cold plates 202 towards the POMs. Between the springs 500 and the associated fluid pressure, each cold plate 202 provides 3-4 lbf of pressure onto the surface of the associated POM while being translatably actuatable to reduce contact resistance.

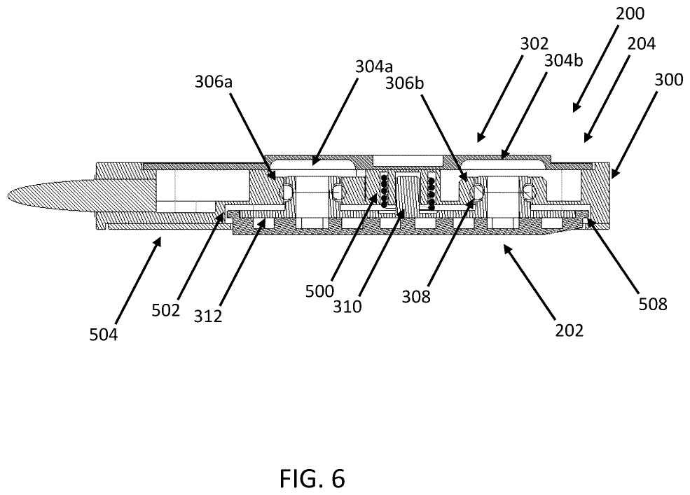

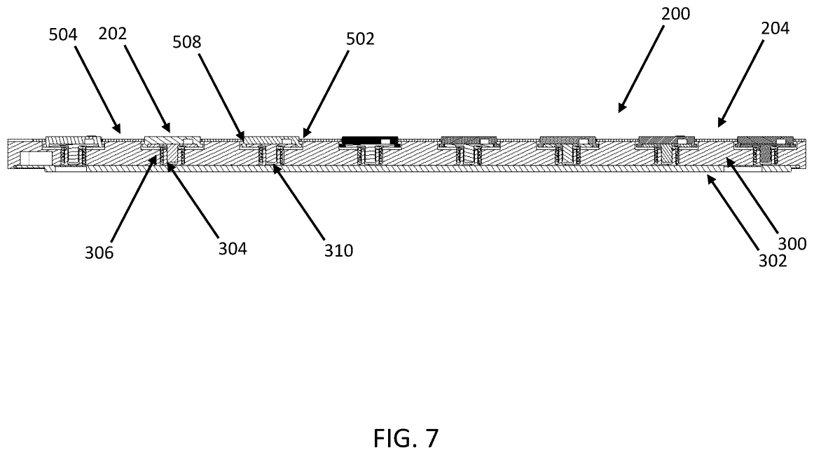

FIGS. 6 and 7 further illustrate a cross-section of the parallel flow liquid cooling distribution assembly 200 of FIG. 2. Again, each of the cold plates 202, of which any number may be used and associated with any number of cages and POMS, is fluidly coupled to the fluid distribution plenum 204 via the inlet piston cylinder 304a and the outlet piston cylinder 304b, each of which is disposed within the corresponding port 306a, 306b of the fluid distribution plenum 204. The O-rings 308 are provided around the piston cylinders 304 to provide the sealing connection that allows relative translation of each of the cold plates 202 with respect to the fluid distribution plenum 204. The spring peg 310 is also provided on the cold plate lid 312 around which the spring 500 is disposed, thereby biasing the cold plates 202 away from the fluid distribution plenum 204 and into the associated POMs. Each of the cold plates 202 sits partially within the conformal recess 502 formed in the body 300 of the fluid distribution plenum 204, and the cold plates 202 are surrounded and retained by the retaining plate 504 secured to the body 300 opposite the lid 302 via the screws 506 or the like, such that the cold plates 202 are depressibly secured to the body 300 of the fluid distribution plenum 204. This securement is accomplished via the lip structure 508 that is disposed around the base perimeter of each of the cold plates 202 and caught or limited by the retaining plate 504. The retaining plate 504 compresses the springs 500 disposed around the spring pegs 310 and serving to bias the cold plates 202 towards the POMs.

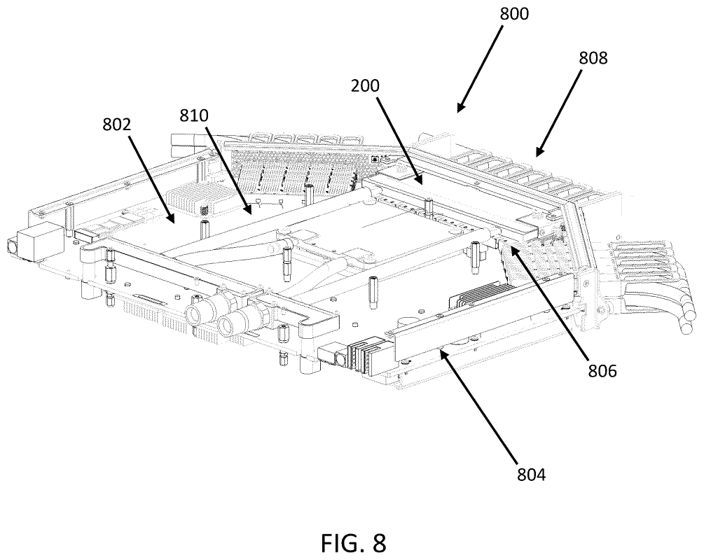

FIG. 8 further illustrates the parallel flow liquid cooling distribution assembly 200 of FIG. 2, highlighting the positioning of the parallel flow liquid cooling distribution assembly in a box 800. The box 800 may be a rack mounted client box, fabric box, or the like and includes a PCB 802 disposed within a case 804. The cages 806 configured to receive the POMs 808 are disposed on the PCB 802 within the case 804. The parallel flow liquid cooling distribution assembly 200 is disposed within the case 804 adjacent to (i.e., above or below) the cages 806 and POMs 808 and is coupled to the main cooling fluid inlet and outlet lines 810 within the case 804. A similar setup may be used on either or both primary and secondary sides of the PCB 802, and be used to cool eight (8) QSFP-DDs on each side, for example, either in an individual or ganged configuration. Using this liquid cooling mechanism, the cooling range, which is limited to about 30 W with air, can be extended to almost double, depending on the inlet temperature of the cooling fluid.

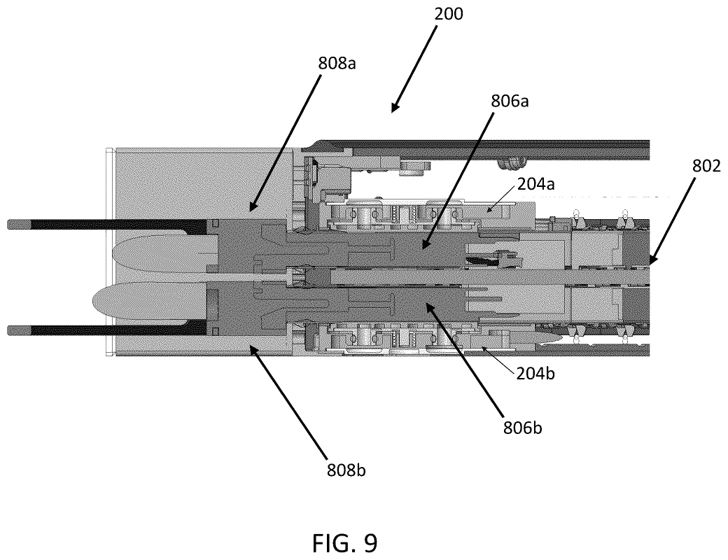

FIG. 9 further illustrates the parallel flow liquid cooling distribution assembly 200 of FIG. 2, highlighting a two side configuration. A primary side fluid distribution plenum 204a is provided on the primary side of the PCB 802 to cool the primary side cages 806a and POMs 808a. A secondary side fluid distribution plenum 204b is provided on the secondary side of the PCB 802 to cool the secondary side cages 806b and POMs 808b.

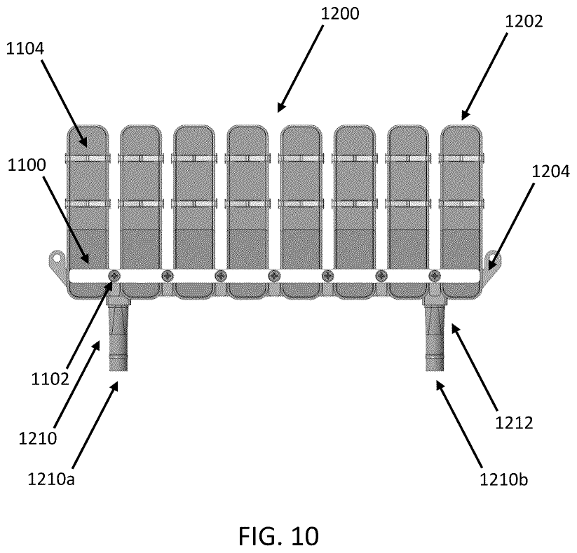

FIG. 10 illustrates another embodiment of the parallel flow liquid cooling distribution assembly 1200 of the present disclosure. Here, the liquid cooling distribution assembly 1200 utilizes an integrated plenum 1204 that is disposed behind the POMs and cages disposed on the PCB of the associated box. Only two (2) tubes 1210, a cool liquid inlet tube 1210a and hot liquid outlet tube 1210b are coupled to the fluid distribution plenum 1204 with connection clamps or fittings 1212 to feed any number of cold plates 1202, which are coupled to the fluid distribution plenum 1204 by the mechanism described in greater detail. This assembly of tubes 1210 and clamps or fittings 1212 takes up significantly less space and eliminates many complex and unreliable fluid connections. Further, the positioning of the fluid distribution plenum 1204 behind the cages and POMs and the use of low profile cold plates 1202 promotes air flow around the cages and POMs, through the faceplate of the box, without obstruction. For example, the height of each of the cold plates 1202 may be limited to 4 mm adjacent to each cage and POM at the front end of the cage (the rear portion can be higher without blocking air into the circuit pack). Here, the flat-ramp structure of the cold plates 1202 utilizes one transition angle, relevant to the manufacturing and brazing process in terms of complexity, filling gaps, etc.

The cold plates 1202 include elongate structures that protrude from the fluid distribution plenum 1204 adjacent to the cages and POMs, with one elongate structure per cage and POM. The elongate structures are secured to the fluid distribution plenum 1204 by a retention member 1100 that traverses one end of each of the elongate structures and is secured to the fluid distribution plenum 1204 via screws 1102 or the like disposed between the elongate structures. When individual cages are utilized, as opposed to ganged cages, each of the elongate structures may also be secured to the cages via conventional clip assemblies 1104 or the like. The retention member 1100 and clip assemblies 1104 serve to bias each of the cold plates 1202 into the associated POM surface when the POM is inserted into the associated cage.

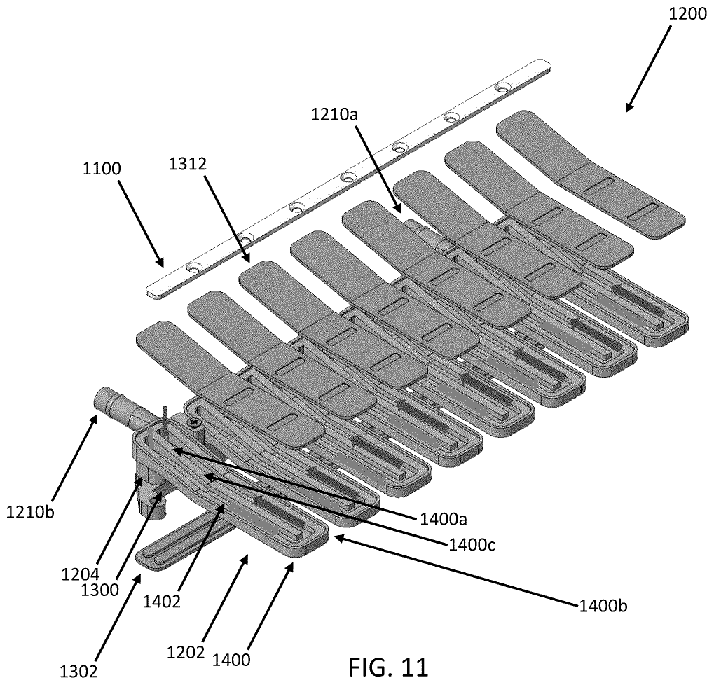

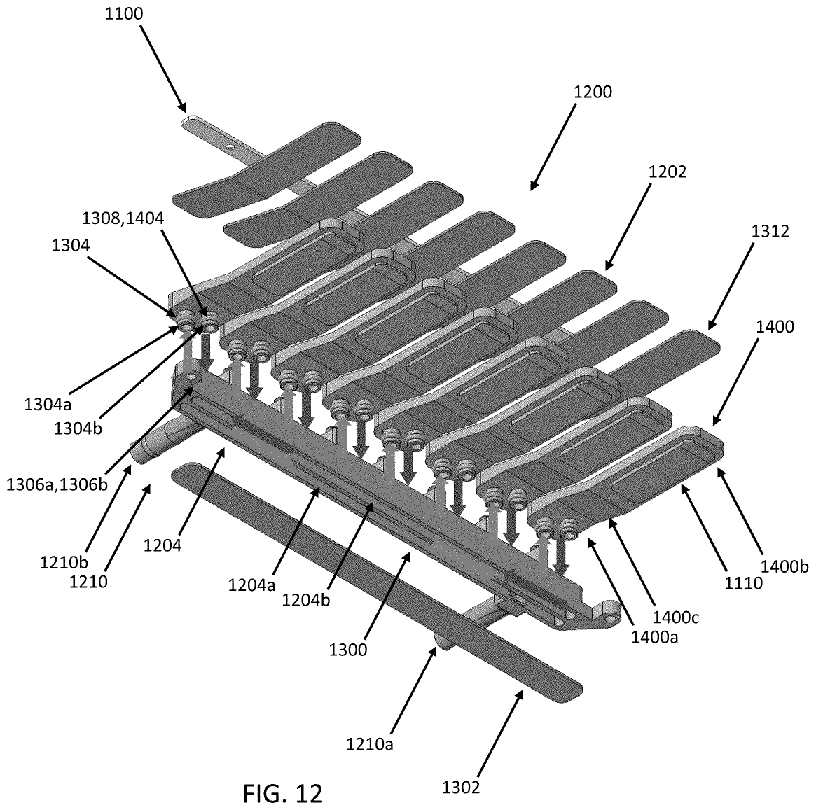

FIGS. 11 and 12 further illustrate the parallel flow liquid cooling distribution assembly 1200 of FIG. 10. The fluid distribution plenum 1204 includes an inlet plenum 1204a and an outlet plenum 1204b integrated into a single structure including a body 1300 and an affixed, sealed lid 1302. The body 1300 and lid 1302 may be made of any suitable rigid material, such as a metallic or plastic material. The inlet tube 1210a is in fluid communication with the inlet plenum 1204a and the outlet tube 1210b is in fluid communication with the outlet plenum 1204b, forming a continuous fluid flow path from the inlet tube 1210a, through the inlet plenum 1204a, through each of the cold plates 1202 in parallel, through the outlet plenum 1204b, and to the outlet tube 1210b, forming a cooling fluid path with the cold plates 1202 disposed in parallel. Each of the cold plates 1202, of which any number may be used and associated with any number of cages and POMS, whether individual or ganged, is fluidly coupled to the fluid distribution plenum 1204 via an inlet piston cylinder 1304a and an outlet piston cylinder 1304b, each of which is disposed within a corresponding inlet/outlet port 1306a, 1306b of the fluid distribution plenum 1204. O-rings 1308 are provided around the piston cylinders 1304 to provide a sealing connection that allows relative translation of each of the cold plates 1202 with respect to the fluid distribution plenum 1204.

Again, the O-rings 1308 are a common mechanism to allow a joint to be sealed but enable a degree of translational and/or rotational movement. The O-rings 1308 are sized to compress into a tightly toleranced groove in a cylinder disposed within a port, for example, allowing fluid to pass through the cylinder and port, and the O-ring 1308 itself, while the cylinder and port are sealed with respect to each other by the O-ring 1308.

The piston arrangement of the present disclosure allows the cooling fluid to be circulated from the fluid distribution plenum 1204 through the cold plates 1202 in parallel, while the cold plates 1202 are biased into the contacted POMs in a height restricted fluid containment application. This parallel cold plate configuration means that the same degree of cooling can be provided to each POM, as the POMs are not cooled in series, which would result in the first cold plate 1202 providing the greatest degree of cooling and the last cold plate 1202 providing the smallest degree of cooling as the cooling fluid is heated along the series. In the parallel cold plate configuration, each cold plate 1202 receives the same cool liquid from the inlet tube 1210a and the inlet plenum 1204a in parallel and provides hot liquid to the outlet plenum 1204b for communication directly to the outlet tube 1210b.

Each cold plate 1202 includes a body 1400 (the elongate structure) that defines a fluid flow path 1402 from the inlet piston cylinder 1304a to the outlet piston cylinder 1304b. The fluid flow path 1402 may be linear, circuitous, and/or could consist of a channel or chamber interrupted by fin structures or the like, well known to those of ordinary skill in the art with respect to such cold plate structures. The body 1400 is sealingly enclosed by the cold plate lid 1312. The inlet piston cylinder 1304a and the outlet piston cylinder 1304b are attached to/through the body 1400. Each piston cylinder 1304a, 1304b includes an external circumferential O-ring groove 1404 in which one of the O-rings 1308 is disposed. It should be noted that the body 1400 of each cold plate 1202 may include a tapered, rounded, and/or ramped external pad 1110 that forms the cooling POM contact portion of the cold plate 1202 and assists in the insertion/removal of the associated POM into the associated cage with the external pad 1110 making contact with the surface of the POM. The body 1400 and cold plate lid 1312 may be made of any suitable rigid material, such as a metallic material.

The body 1400 of each cold plate 1202 may include a first planar portion 1400a corresponding to the fluid distribution plenum 1204 and a second planar portion 1400b corresponding to the associated cage and POM and including the external pad 1110. The first planar portion 1400a may be adjoined to the second planar portion 1400b via a ramped transition portion 1400c, with the first planar portion 1400a and the second planar portion 1400b being disposed in different planes. This allows the height of the cold plates 1202 above the cages and POMs to be minimized, promoting air flow around the cages and POMs.

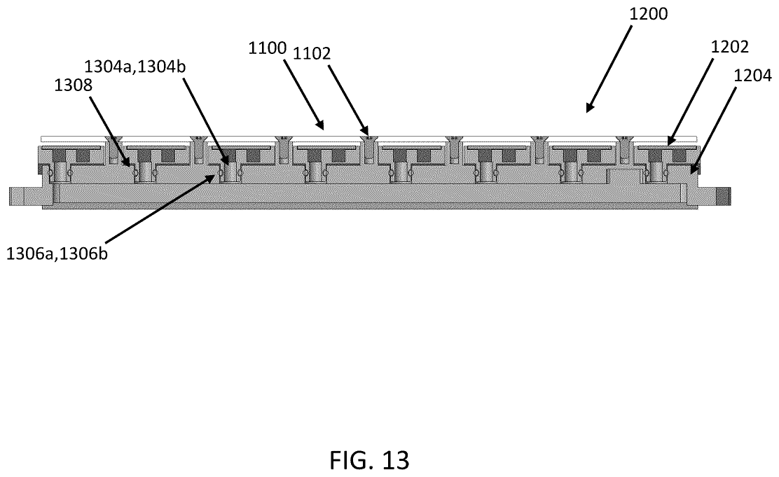

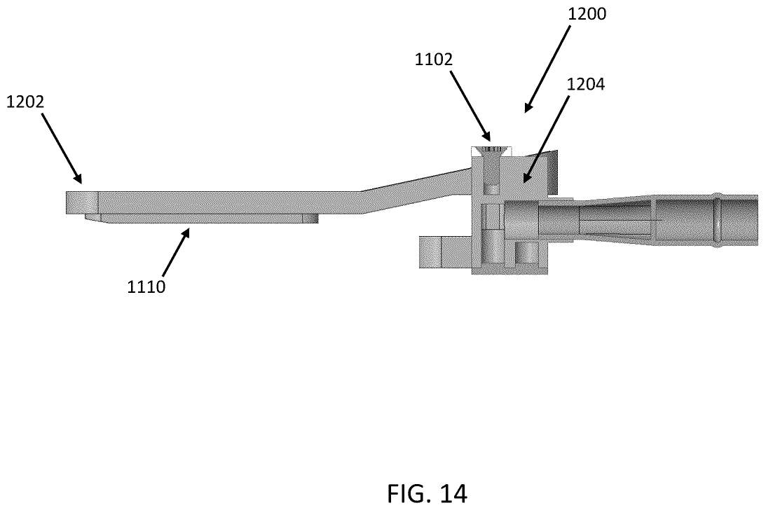

FIGS. 13 and 14 further illustrate the parallel flow liquid cooling distribution assembly 1200 of FIG. 10. Again, each of the cold plates 1202, of which any number may be used and associated with any number of cages and POMS, is fluidly coupled to the fluid distribution plenum 1204 via the inlet piston cylinder 1304a and the outlet piston cylinder 1304b, each of which is disposed within the corresponding port 1306a, 1306b of the fluid distribution plenum 1204. The O-rings 1308 are provided around the piston cylinders 1304 to provide the sealing connection that allows relative translation of each of the cold plates 1202 with respect to the fluid distribution plenum 1204. Securement is accomplished via the retention member 1100 that traverses one end of each of the cold plates 1202 is secured to the fluid distribution plenum 1204 via the screws 1102 or the like disposed between the cold plates 1202. The external pad 1110 makes contact with the surface of the associated POM through the associated cage.

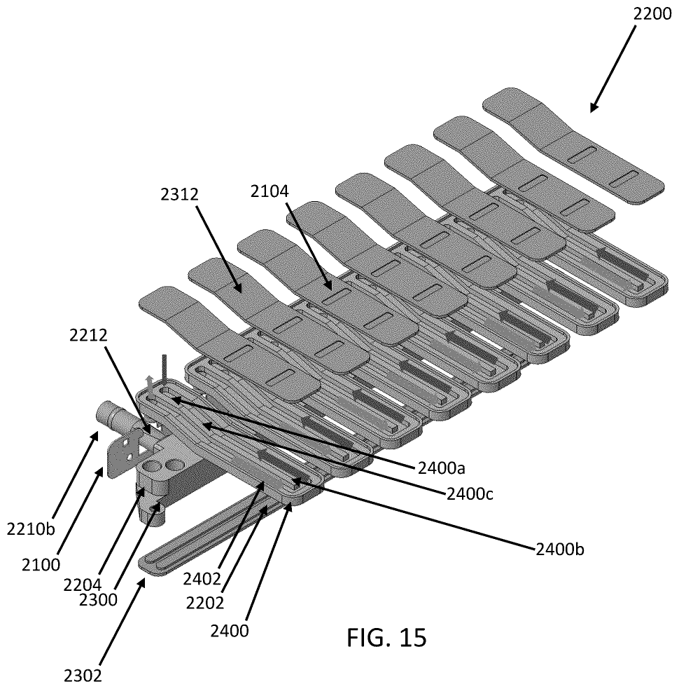

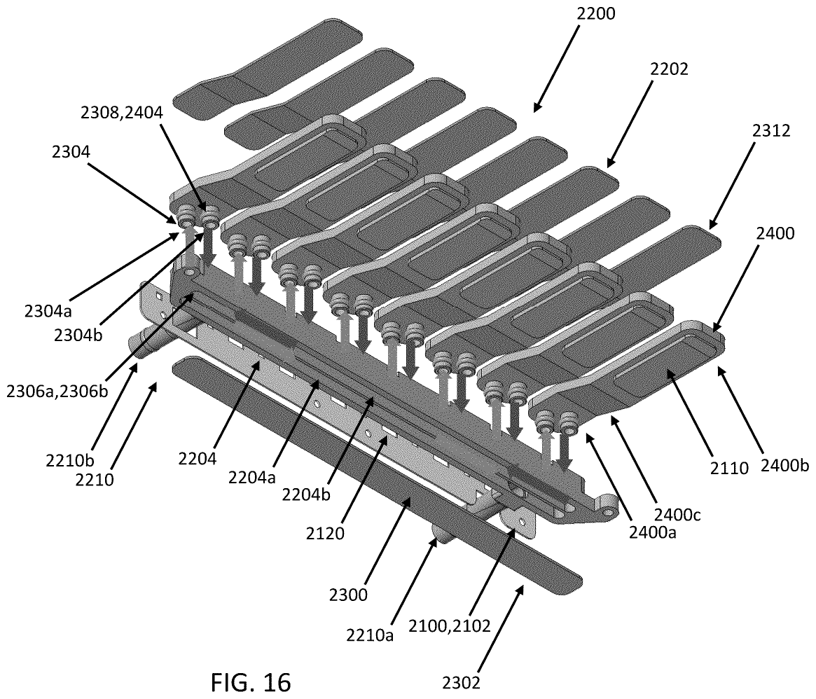

FIGS. 15 and 16 illustrate a further embodiment of the parallel flow liquid cooling distribution assembly 2200 of the present disclosure. Here, the liquid cooling distribution assembly 2200 utilizes an integrated plenum 2204 that is disposed behind the POMs and cages disposed on the PCB of the associated box. Only two (2) tubes 2210, a cool liquid inlet tube 2210a and hot liquid outlet tube 2210b are coupled to the fluid distribution plenum 2204 with connection clamps or fittings 2212 to feed any number of cold plates 2202, which are coupled to the fluid distribution plenum 2204 by the mechanism described in greater detail. This assembly of tubes 2210 and clamps or fittings 2212 takes up significantly less space and eliminates many complex and unreliable fluid connections. Further, the positioning of the fluid distribution plenum 2204 behind the cages and POMs and the use of low profile cold plates 2202 promotes air flow around the cages and POMs, through the faceplate of the box, without obstruction. For example, the height of each of the cold plates 2202 may be limited to 4 mm adjacent to each cage and POM at the front end of the cage (the rear portion can be higher without blocking air into the circuit pack). Here, the flat-ramp-flat structure of the cold plates 2202 utilizes two transition angles, relevant to the manufacturing and brazing process in terms of complexity, filling gaps, etc.

The cold plates 2202 include elongate structures that protrude from the fluid distribution plenum 2204 adjacent to the cages and POMs, with one elongate structure per cage and POM. The elongate structures are secured to the fluid distribution plenum 2204 by a retention plate 2100 that traverses one end of each of the elongate structures and is secured to the fluid distribution plenum 2204 via screws 2102 or the like. When individual cages are utilized, as opposed to ganged cages, each of the elongate structures may also be secured to the cages via conventional clip assemblies 2104 or the like. The retention plate 2100 and clip assemblies 2104 serve to bias each of the cold plates 2202 into the associated POM surface when the POM is inserted into the associated cage. The configuration of the retention plate 2100 is described in greater detail, however the retention plate 2100 generally runs along the rear of the fluid distribution plenum 2204 and the cold plates 2202.

The fluid distribution plenum 2204 includes an inlet plenum 2204a and an outlet plenum 2204b integrated into a single structure including a body 2300 and an affixed, sealed lid 2302. The body 2300 and lid 2302 may be made of any suitable rigid material, such as a metallic or plastic material. The inlet tube 2210a is in fluid communication with the inlet plenum 2204a and the outlet tube 2210b is in fluid communication with the outlet plenum 2204b, forming a continuous fluid flow path from the inlet tube 2210a, through the inlet plenum 2204a, through each of the cold plates 2202 in parallel, through the outlet plenum 2204b, and to the outlet tube 2210b, forming a cooling fluid path with the cold plates 2202 disposed in parallel. Each of the cold plates 2202, of which any number may be used and associated with any number of cages and POMS, whether individual or ganged, is fluidly coupled to the fluid distribution plenum 2204 via an inlet piston cylinder 2304a and an outlet piston cylinder 2304b, each of which is disposed within a corresponding inlet/outlet port 2306a,2306b of the fluid distribution plenum 2204. O-rings 2308 are provided around the piston cylinders 2304 to provide a sealing connection that allows relative translation of each of the cold plates 2202 with respect to the fluid distribution plenum 2204.

Again, the O-rings 2308 are a common mechanism to allow a joint to be sealed but enable a degree of translational and/or rotational movement. The O-rings 2308 are sized to compress into a tightly toleranced groove in a cylinder disposed within a port, for example, allowing fluid to pass through the cylinder and port, and the O-ring 2308 itself, while the cylinder and port are sealed with respect to each other by the O-ring 2308.

The piston arrangement of the present disclosure allows the cooling fluid to be circulated from the fluid distribution plenum 2204 through the cold plates 2202 in parallel, while the cold plates 2202 are biased into the contacted POMs in a height restricted fluid containment application. This parallel cold plate configuration means that the same degree of cooling can be provided to each POM, as the POMs are not cooled in series, which would result in the first cold plate 2202 providing the greatest degree of cooling and the last cold plate 2202 providing the smallest degree of cooling as the cooling fluid is heated along the series. In the parallel cold plate configuration, each cold plate 2202 receives the same cool liquid from the inlet tube 2210a and the inlet plenum 2204a in parallel and provides hot liquid to the outlet plenum 2204b for communication directly to the outlet tube 2210b.

Each cold plate 2202 includes a body 2400 (the elongate structure) that defines a fluid flow path 2402 from the inlet piston cylinder 2304a to the outlet piston cylinder 2304b. The fluid flow path 2402 may be linear, circuitous, and/or could consist of a channel or chamber interrupted by fin structures or the like, well known to those of ordinary skill in the art with respect to such cold plate structures. The body 2400 is sealingly enclosed by the cold plate lid 2312. The inlet piston cylinder 2304a and the outlet piston cylinder 2304b are attached to/through the body 2400. Each piston cylinder 2304a,2304b includes an external circumferential O-ring groove 2404 in which one of the O-rings 2308 is disposed. It should be noted that the body 2400 of each cold plate 2202 may include a tapered, rounded, and/or ramped external pad 2110 that forms the cooling POM contact portion of the cold plate 2202 and assists in the insertion/removal of the associated POM into the associated cage with the external pad 2110 making contact with the surface of the POM. The body 2400 and cold plate lid 2312 may be made of any suitable rigid material, such as a metallic material.

The body 2400 of each cold plate 2202 may include a first planar portion 2400a corresponding to the fluid distribution plenum 2204 and a second planar portion 2400b corresponding to the associated cage and POM and including the external pad 2110. The first planar portion 2400a may be adjoined to the second planar portion 2400b via a ramped transition portion 2400c, with the first planar portion 2400a and the second planar portion 2400b being disposed in different planes. This allows the height of the cold plates 2202 above the cages and POMs to be minimized, promoting air flow around the cages and POMs.

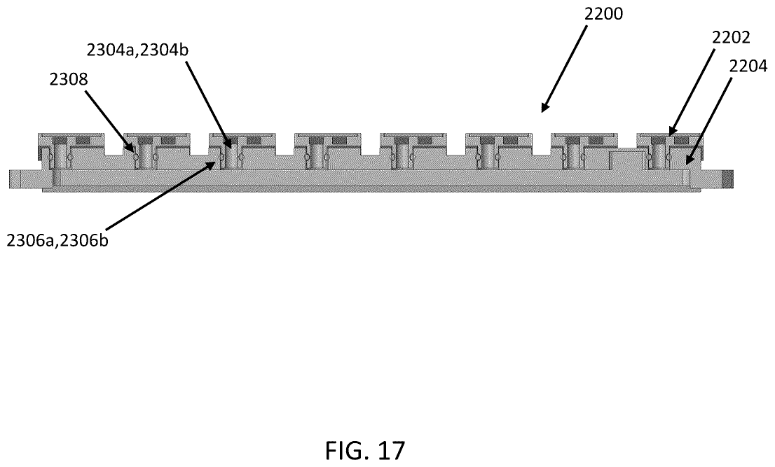

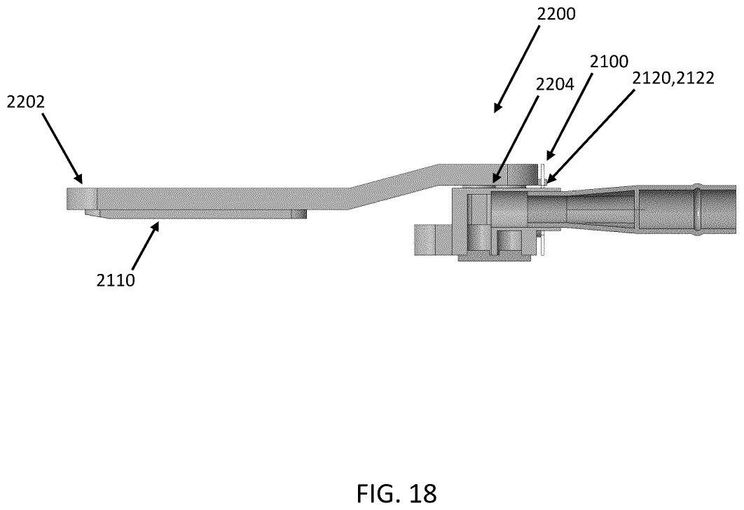

FIGS. 17 and 18 further illustrate the parallel flow liquid cooling distribution assembly 2200 of FIGS. 15 and 16. Again, each of the cold plates 2202, of which any number may be used and associated with any number of cages and POMS, is fluidly coupled to the fluid distribution plenum 2204 via the inlet piston cylinder 2304a and the outlet piston cylinder 2304b, each of which is disposed within the corresponding port 2306a,2306b of the fluid distribution plenum 2204. The O-rings 2308 are provided around the piston cylinders 2304 to provide the sealing connection that allows relative translation of each of the cold plates 2202 with respect to the fluid distribution plenum 2204. Securement is accomplished via the retention plate 2100 that traverses the rear of the fluid distribution plenum 2204 and one end of each of the cold plates 2202 is secured to the fluid distribution plenum 1204 via the screws 2102 or the like. The external pad 2110 makes contact with the surface of the associated POM through the associated cage.

Referring to FIGS. 16 and 18, the retention plate 2100 defines slots 2120 that are sized to capture associated tabs 2122 provided at the rear end of the cold plates 2202. These slots 2120 may be oversized in relation to the tabs 2122 (at least vertically), such that the cold plates 2202 may be provided with a degree of movement with respect to the fluid distribution plenum 2204, cages, and POMs (at least vertically), with relative translation provided along the axis of each of the fluid connections of the piston mechanisms. The use of the rear retention plate 2100 further reduces the vertical footprint of the parallel flow liquid cooling distribution assembly 2200.

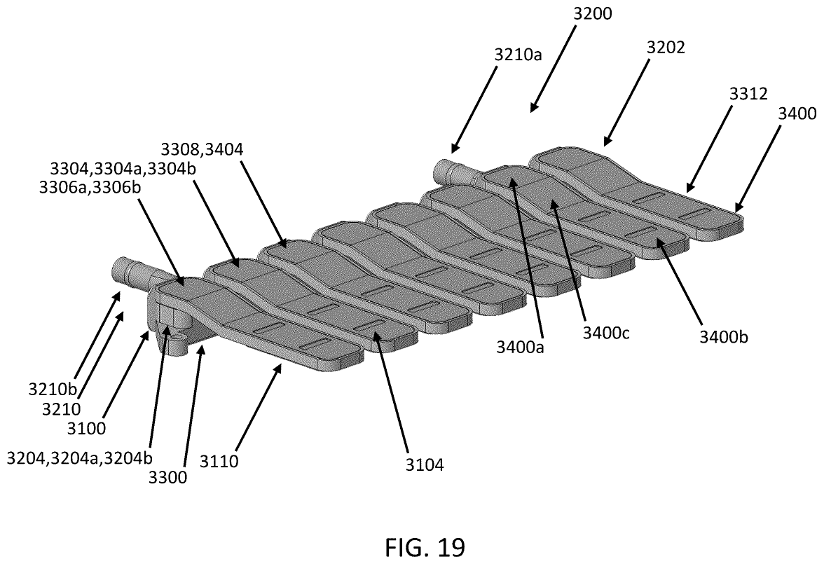

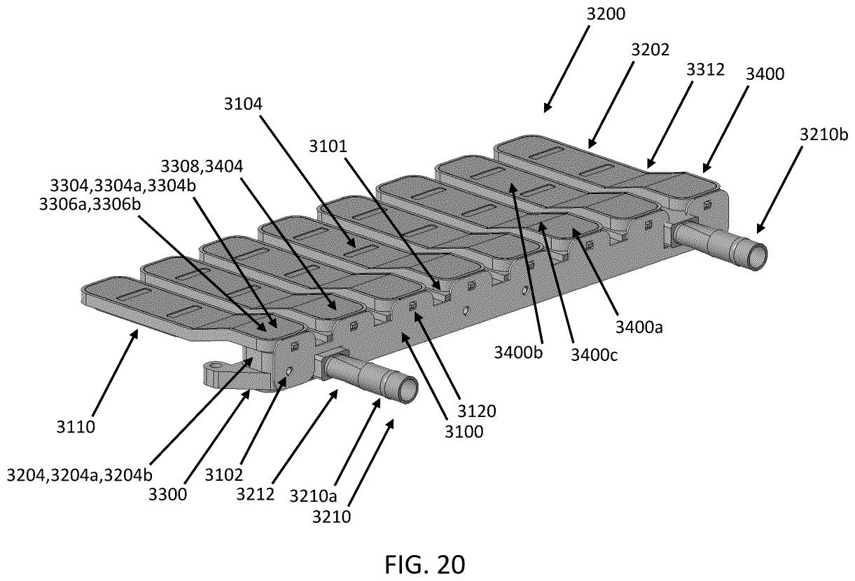

FIGS. 19 and 20 illustrate a further embodiment of the parallel flow liquid cooling distribution assembly 3200 of the present disclosure. Here, the liquid cooling distribution assembly 3200 utilizes an integrated plenum 3204 that is disposed behind the POMs and cages disposed on the PCB of the associated box. Only two (2) tubes 3210, a cool liquid inlet tube 3210a and hot liquid outlet tube 3210b are coupled to the fluid distribution plenum 3204 with connection clamps or fittings 3212 to feed any number of cold plates 3202, which are coupled to the fluid distribution plenum 3204 by the mechanism described in greater detail. This assembly of tubes 3210 and clamps or fittings 3212 takes up significantly less space and eliminates many complex and unreliable fluid connections. Further, the positioning of the fluid distribution plenum 3204 behind the cages and POMs and the use of low profile cold plates 3202 promotes air flow around the cages and POMs, through the faceplate of the box, without obstruction. For example, the height of each of the cold plates 3202 may be limited to 4 mm adjacent to each cage and POM at the front end of the cage (the rear portion can be higher without blocking air into the circuit pack).

The cold plates 3202 include elongate structures that protrude from the fluid distribution plenum 3204 adjacent to the cages and POMs, with one elongate structure per cage and POM. The elongate structures are secured to the fluid distribution plenum 3204 by a retention plate 3100 that traverses one end of each of the elongate structures and is secured to the fluid distribution plenum 3204 via screws 3102 or the like. When individual cages are utilized, as opposed to ganged cages, each of the elongate structures may also be secured to the cages via conventional clip assemblies 3104 or the like. The retention plate 3100 and clip assemblies 3104 serve to bias each of the cold plates 3202 into the associated POM surface when the POM is inserted into the associated cage. The configuration of the retention plate 3100 is described in greater detail, however the retention plate 3100 generally runs along the rear of the fluid distribution plenum 3204 and the cold plates 3202.

The fluid distribution plenum 3204 includes an inlet plenum 3204a and an outlet plenum 3204b integrated into a single structure including a body 3300 and an affixed, sealed lid 3302. The body 3300 and lid 3302 may be made of any suitable rigid material, such as a metallic or plastic material. The inlet tube 3210a is in fluid communication with the inlet plenum 3204a and the outlet tube 3210b is in fluid communication with the outlet plenum 3204b, forming a continuous fluid flow path from the inlet tube 3210a, through the inlet plenum 3204a, through each of the cold plates 3202 in parallel, through the outlet plenum 3204b, and to the outlet tube 3210b, forming a cooling fluid path with the cold plates 3202 disposed in parallel. Each of the cold plates 3202, of which any number may be used and associated with any number of cages and POMS, whether individual or ganged, is fluidly coupled to the fluid distribution plenum 3204 via an inlet piston cylinder 3304a and an outlet piston cylinder 3304b, each of which is disposed within a corresponding inlet/outlet port 3306a,3306b of the fluid distribution plenum 3204. O-rings 3308 are provided around the piston cylinders 3304 to provide a sealing connection that allows relative translation of each of the cold plates 3202 with respect to the fluid distribution plenum 3204.

The piston arrangement of the present disclosure allows the cooling fluid to be circulated from the fluid distribution plenum 3204 through the cold plates 3202 in parallel, while the cold plates 3202 are biased into the contacted POMs in a height restricted fluid containment application. This parallel cold plate configuration means that the same degree of cooling can be provided to each POM, as the POMs are not cooled in series, which would result in the first cold plate 3202 providing the greatest degree of cooling and the last cold plate 3202 providing the smallest degree of cooling as the cooling fluid is heated along the series. In the parallel cold plate configuration, each cold plate 3202 receives the same cool liquid from the inlet tube 3210a and the inlet plenum 3204a in parallel and provides hot liquid to the outlet plenum 3204b for communication directly to the outlet tube 3210b.

Each cold plate 3202 includes a body 3400 (the elongate structure) that defines a fluid flow path 3402 from the inlet piston cylinder 3304a to the outlet piston cylinder 3304b. The fluid flow path 3402 may be linear, circuitous, and/or could consist of a channel or chamber interrupted by fin structures or the like, well known to those of ordinary skill in the art with respect to such cold plate structures. The body 3400 is sealingly enclosed by the cold plate lid 3312. The inlet piston cylinder 3304a and the outlet piston cylinder 3304b are attached to/through the body 3400. Each piston cylinder 3304a,3304b includes an external circumferential O-ring groove 3404 in which one of the O-rings 3308 is disposed. It should be noted that the body 3400 of each cold plate 3202 may include a tapered, rounded, and/or ramped external pad 3110 that forms the cooling POM contact portion of the cold plate 3202 and assists in the insertion/removal of the associated POM into the associated cage with the external pad 3110 making contact with the surface of the POM. The body 3400 and cold plate lid 3312 may be made of any suitable rigid material, such as a metallic material.

The body 3400 of each cold plate 3202 may include a first planar portion 3400a corresponding to the fluid distribution plenum 3204 and a second planar portion 3400b corresponding to the associated cage and POM and including the external pad 3110. The first planar portion 3400a may be adjoined to the second planar portion 3400b via a ramped transition portion 3400c, with the first planar portion 3400a and the second planar portion 3400b being disposed in different planes. This allows the height of the cold plates 3202 above the cages and POMs to be minimized, promoting air flow around the cages and POMs.

The retention plate 3100 defines slots 3120 that are sized to capture associated tabs 3122 provided at the rear end of the cold plates 3202. These slots 3120 may be oversized in relation to the tabs 3122 (at least vertically), such that the cold plates 3202 may be provided with a degree of movement with respect to the fluid distribution plenum 3204, cages, and POMs (at least vertically), with relative translation provided along the axis of each of the fluid connections of the piston mechanisms. The use of the rear retention plate 3100 further reduces the vertical footprint of the parallel flow liquid cooling distribution assembly 2200. The retention plate 3100 may include cutouts or narrowed regions 3101 that further reduce the vertical footprint of the parallel flow liquid cooling distribution assembly 2200.

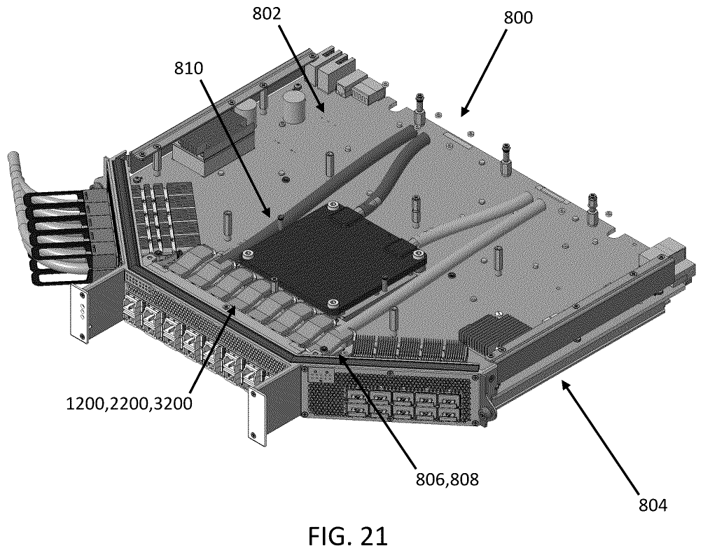

FIG. 21 further illustrates the parallel flow liquid cooling distribution assembly 1200,2200,3200, highlighting the positioning of the parallel flow liquid cooling distribution assembly 1200,2200,3200 in a box 800. The box 800 may again be a rack mounted client box, fabric box, or the like and includes the PCB 802 disposed within the case 804. The cages 806 configured to receive the POMs 808 are disposed on the PCB 802 within the case 804. The parallel flow liquid cooling distribution assembly 1200,2200,3200 is disposed within the case 804 adjacent to the cages 806 and POMs 808 and is coupled to the main cooling fluid inlet and outlet lines 810 within the case 804. A similar setup may be used on either or both primary and secondary sides of the PCB 802, and be used to cool eight (8) QSFP-DDs on each side, for example, either in an individual or ganged configuration. Using this liquid cooling mechanism, the cooling range, which is limited to about 30 W with air, can be extended to almost double, depending on the inlet temperature of the cooling fluid.

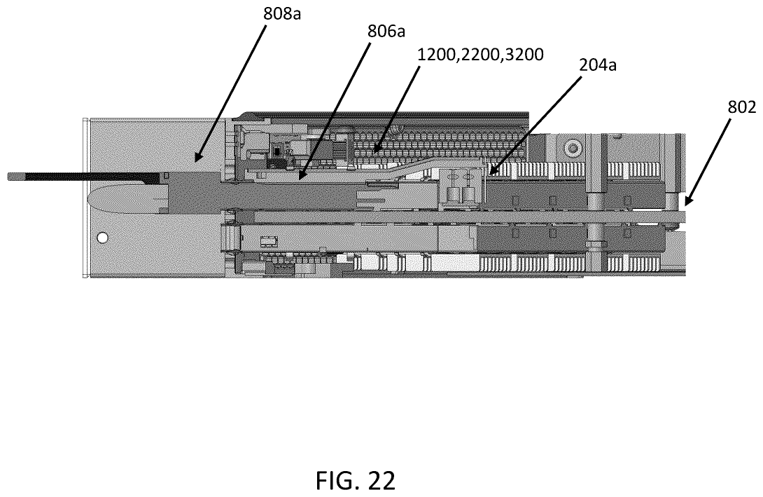

FIG. 22 further illustrates the parallel flow liquid cooling distribution assembly 1200,2200,3200, highlighting a one side configuration. A primary side fluid distribution plenum 204a is provided on the primary side of the PCB 802 to cool the primary side cages 806a and POMs 808a. It will be readily apparent to those of ordinary skill in the art that a secondary side fluid distribution plenum 204b may also be provided on the secondary side of the PCB 802 to cool the secondary side cages 806b and POMs 808b (see FIG. 9).

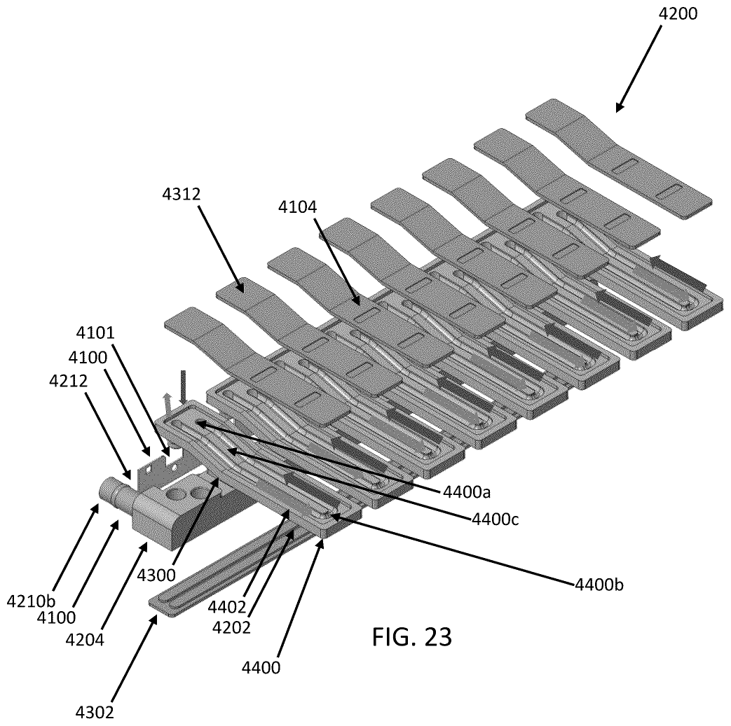

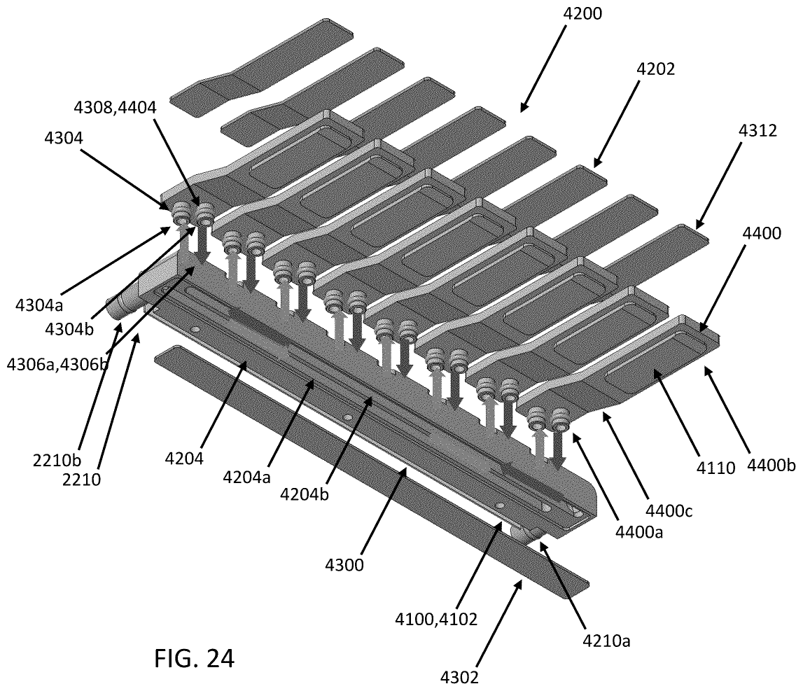

FIGS. 23 and 24 illustrate a further embodiment of the parallel flow liquid cooling distribution assembly 4200 of the present disclosure. Here, the liquid cooling distribution assembly 4200 utilizes an integrated plenum 4204 that is disposed behind the POMs and cages disposed on the PCB of the associated box. Only two (2) tubes 4210, a cool liquid inlet tube 4210a and hot liquid outlet tube 4210b are coupled to the fluid distribution plenum 4204 with connection clamps or fittings 4212 to feed any number of cold plates 4202, which are coupled to the fluid distribution plenum 4204 by the mechanism described in greater detail. This assembly of tubes 4210 and clamps or fittings 4212 takes up significantly less space and eliminates many complex and unreliable fluid connections. Further, the positioning of the fluid distribution plenum 4204 behind the cages and POMs and the use of low profile cold plates 4202 promotes air flow around the cages and POMs, through the faceplate of the box, without obstruction. For example, the height of each of the cold plates 4202 may be limited to 4 mm adjacent to each cage and POM at the front end of the cage (the rear portion can be higher without blocking air into the circuit pack).

The cold plates 4202 include elongate structures that protrude from the fluid distribution plenum 4204 adjacent to the cages and POMs, with one elongate structure per cage and POM. The elongate structures are secured to the fluid distribution plenum 4204 by a retention plate 4100 that traverses one end of each of the elongate structures and is secured to the fluid distribution plenum 4204 via screws 4102 or the like. When individual cages are utilized, as opposed to ganged cages, each of the elongate structures may also be secured to the cages via conventional clip assemblies 4104 or the like. The retention plate 4100 and clip assemblies 4104 serve to bias each of the cold plates 4202 into the associated POM surface when the POM is inserted into the associated cage. The configuration of the retention plate 4100 is described in greater detail, however the retention plate 4100 generally runs along the rear of the fluid distribution plenum 4204 and the cold plates 4202.

The fluid distribution plenum 4204 includes an inlet plenum 4204a and an outlet plenum 4204b integrated into a single structure including a body 4300 and an affixed, sealed lid 4302. The body 4300 and lid 4302 may be made of any suitable rigid material, such as a metallic or plastic material. The inlet tube 4210a is in fluid communication with the inlet plenum 4204a and the outlet tube 4210b is in fluid communication with the outlet plenum 4204b, forming a continuous fluid flow path from the inlet tube 4210a, through the inlet plenum 4204a, through each of the cold plates 4202 in parallel, through the outlet plenum 4204b, and to the outlet tube 4210b, forming a cooling fluid path with the cold plates 4202 disposed in parallel. Each of the cold plates 4202, of which any number may be used and associated with any number of cages and POMS, whether individual or ganged, is fluidly coupled to the fluid distribution plenum 4204 via an inlet piston cylinder 4304a and an outlet piston cylinder 4304b, each of which is disposed within a corresponding inlet/outlet port 4306a,4306b of the fluid distribution plenum 4204. O-rings 4308 are provided around the piston cylinders 4304 to provide a sealing connection that allows relative translation of each of the cold plates 4202 with respect to the fluid distribution plenum 4204.

The piston arrangement of the present disclosure allows the cooling fluid to be circulated from the fluid distribution plenum 4204 through the cold plates 4202 in parallel, while the cold plates 4202 are biased into the contacted POMs in a height restricted fluid containment application. This parallel cold plate configuration means that the same degree of cooling can be provided to each POM, as the POMs are not cooled in series, which would result in the first cold plate 4202 providing the greatest degree of cooling and the last cold plate 4202 providing the smallest degree of cooling as the cooling fluid is heated along the series. In the parallel cold plate configuration, each cold plate 4202 receives the same cool liquid from the inlet tube 4210a and the inlet plenum 4204a in parallel and provides hot liquid to the outlet plenum 4204b for communication directly to the outlet tube 4210b.

Each cold plate 4202 includes a body 4400 (the elongate structure) that defines a fluid flow path 4402 from the inlet piston cylinder 4304a to the outlet piston cylinder 4304b. The fluid flow path 4402 may be linear, circuitous, and/or could consist of a channel or chamber interrupted by fin structures or the like, well known to those of ordinary skill in the art with respect to such cold plate structures. The body 4400 is sealingly enclosed by the cold plate lid 4312. The inlet piston cylinder 4304a and the outlet piston cylinder 4304b are attached to/through the body 4400. Each piston cylinder 4304a,4304b includes an external circumferential O-ring groove 4404 in which one of the O-rings 4308 is disposed. It should be noted that the body 4400 of each cold plate 4202 may include a tapered, rounded, and/or ramped external pad 4110 that forms the cooling POM contact portion of the cold plate 4202 and assists in the insertion/removal of the associated POM into the associated cage with the external pad 4110 making contact with the surface of the POM. The body 4400 and cold plate lid 4312 may be made of any suitable rigid material, such as a metallic material.

The body 4400 of each cold plate 4202 may include a first planar portion 4400a corresponding to the fluid distribution plenum 4204 and a second planar portion 4400b corresponding to the associated cage and POM and including the external pad 4110. The first planar portion 4400a may be adjoined to the second planar portion 4400b via a ramped transition portion 4400c, with the first planar portion 4400a and the second planar portion 4400b being disposed in different planes. This allows the height of the cold plates 4202 above the cages and POMs to be minimized, promoting air flow around the cages and POMs.

The retention plate 4100 defines slots 4120 that are sized to capture associated tabs 4122 provided at the rear end of the cold plates 4202. These slots 4120 may be oversized in relation to the tabs 4122 (at least vertically), such that the cold plates 4202 may be provided with a degree of movement with respect to the fluid distribution plenum 4204, cages, and POMs (at least vertically), with relative translation provided along the axis of each of the fluid connections of the piston mechanisms. The use of the rear retention plate 4100 further reduces the vertical footprint of the parallel flow liquid cooling distribution assembly 4200. The retention plate 4100 may include cutouts or narrowed regions 4101 that further reduce the vertical footprint of the parallel flow liquid cooling distribution assembly 4200.

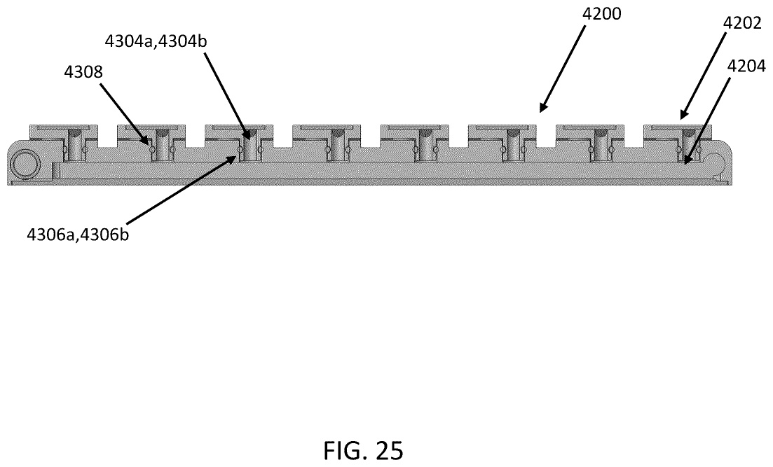

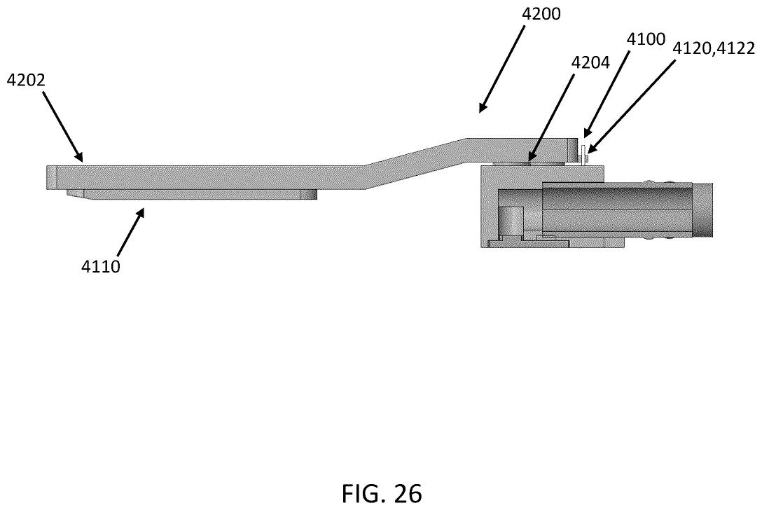

FIGS. 25 and 26 further illustrate the parallel flow liquid cooling distribution assembly 4200 of FIGS. 23 and 24. Again, each of the cold plates 4202, of which any number may be used and associated with any number of cages and POMS, is fluidly coupled to the fluid distribution plenum 4204 via the inlet piston cylinder 4304a and the outlet piston cylinder 4304b, each of which is disposed within the corresponding port 4306a,4306b of the fluid distribution plenum 4204. The O-rings 4308 are provided around the piston cylinders 4304 to provide the sealing connection that allows relative translation of each of the cold plates 4202 with respect to the fluid distribution plenum 4204. Securement is accomplished via the retention plate 4100 that traverses the rear of the fluid distribution plenum 4204 and one end of each of the cold plates 4202 is secured to the fluid distribution plenum 4204 via the screws 4102 or the like. The external pad 4110 makes contact with the surface of the associated POM through the associated cage.

The retention plate 4100 defines slots 4120 that are sized to capture associated tabs 4122 provided at the rear end of the cold plates 4202. These slots 4120 may be oversized in relation to the tabs 4122 (at least vertically), such that the cold plates 4202 may be provided with a degree of movement with respect to the fluid distribution plenum 4204, cages, and POMs (at least vertically), with relative translation provided along the axis of each of the fluid connections of the piston mechanisms. The use of the rear retention plate 4100 further reduces the vertical footprint of the parallel flow liquid cooling distribution assembly 4200.

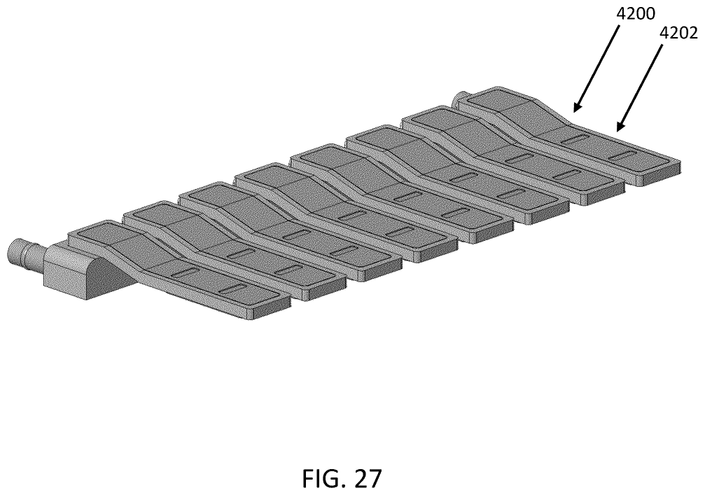

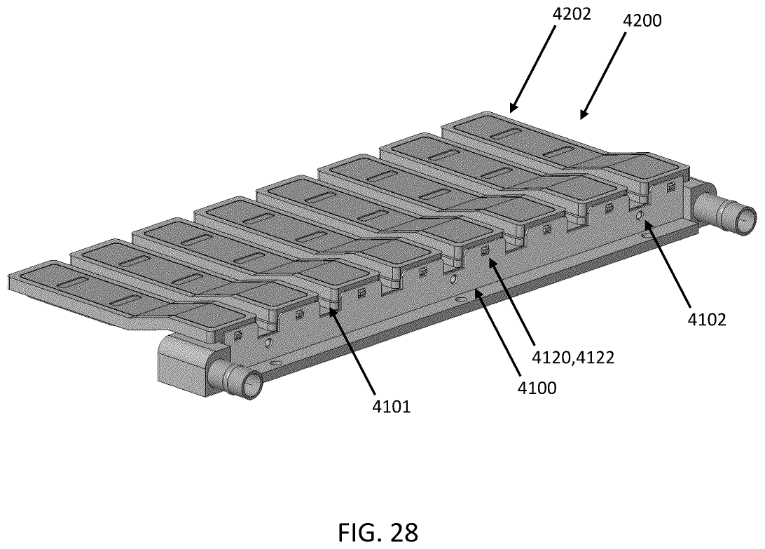

FIGS. 27 and 28 illustrate a further embodiment of the parallel flow liquid cooling distribution assembly 4200 of the present disclosure, highlighting the configuration of the retention plate 4100 and the associated screws 4102, slots 4102, tabs 4122, and cutouts 4101. It should be noted that, to maximize air flow, the cutouts 4101 are aligned with the spaces between the cold plates 4202.

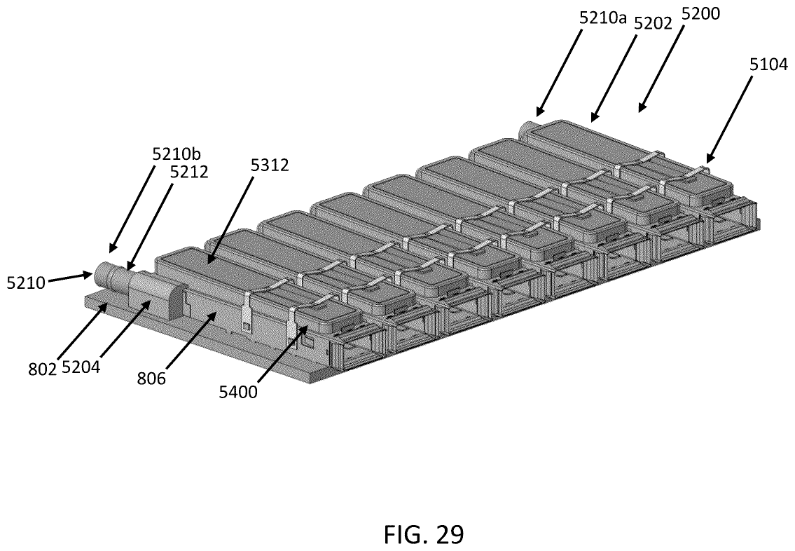

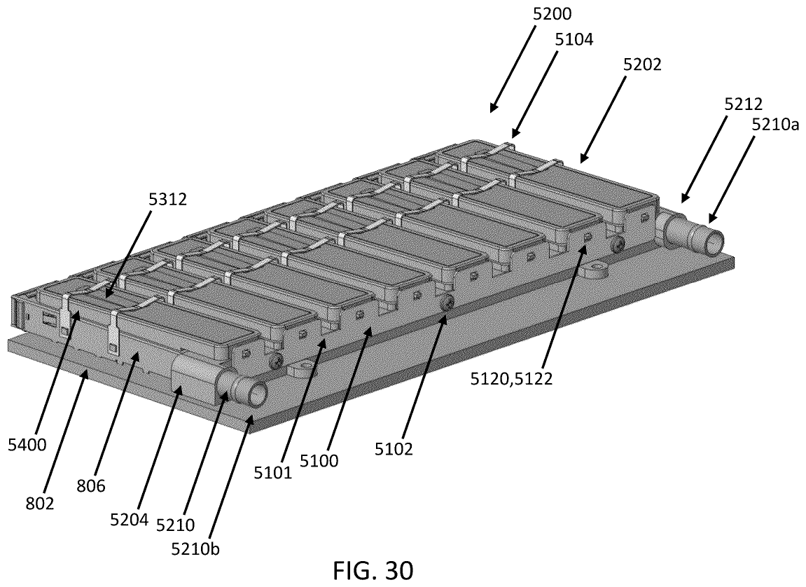

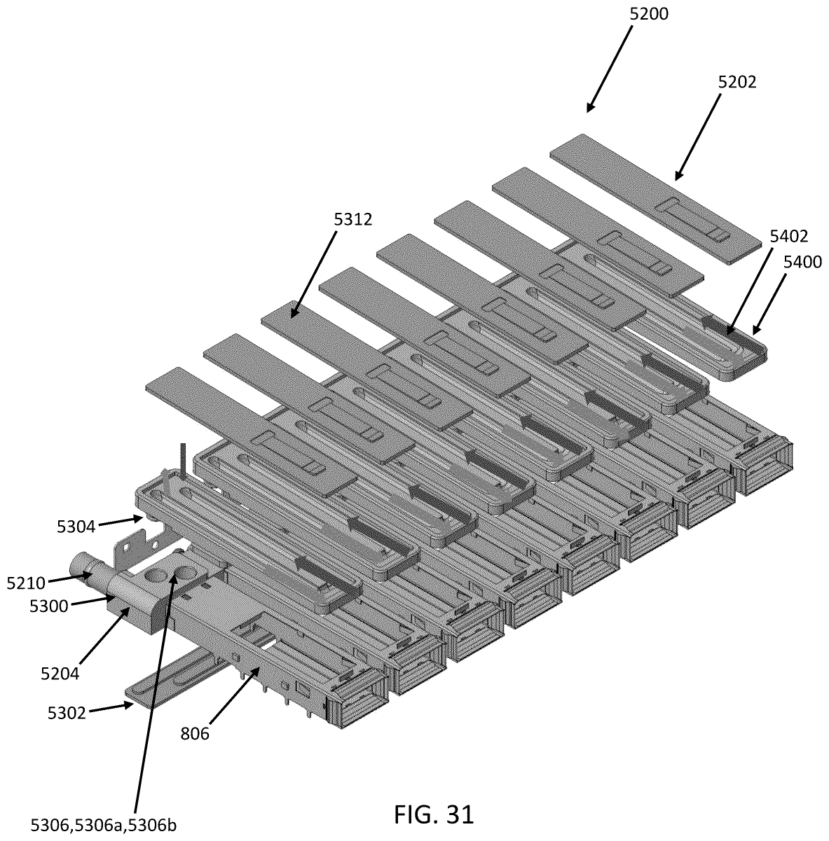

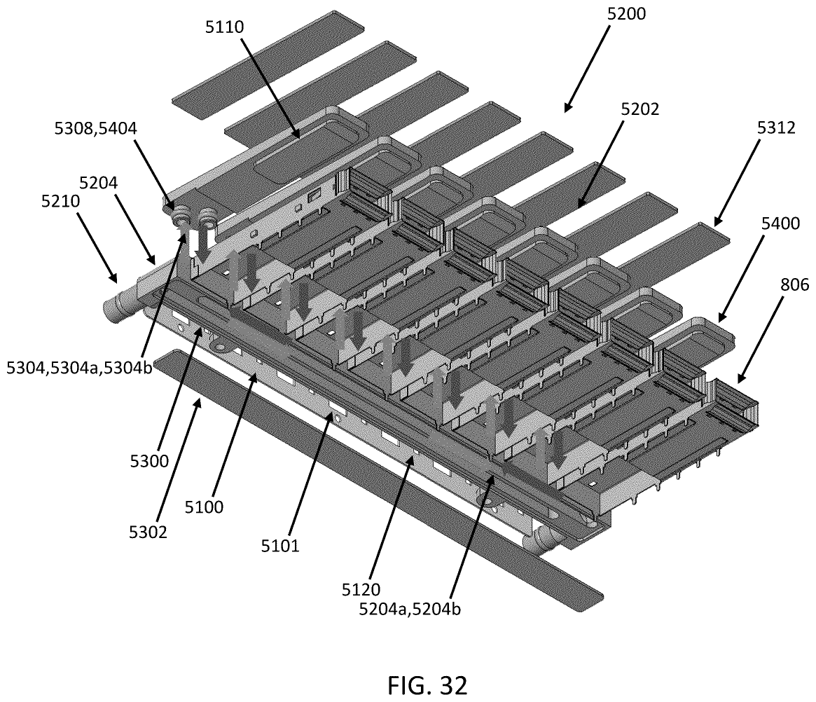

FIGS. 29-32 illustrate a further embodiment of the parallel flow liquid cooling distribution assembly 5200 of the present disclosure. Here, the liquid cooling distribution assembly 5200 utilizes an integrated plenum 5204 that is disposed behind the POMs and cages 806 disposed on the PCB 802 of the associated box. Only two (2) tubes 5210, a cool liquid inlet tube 5210a and hot liquid outlet tube 5210b are coupled to the fluid distribution plenum 5204 with connection clamps or fittings 5212 to feed any number of cold plates 5202, which are coupled to the fluid distribution plenum 5204 by the mechanism described in greater detail. This assembly of tubes 5210 and clamps or fittings 5212 takes up significantly less space and eliminates many complex and unreliable fluid connections. Further, the positioning of the fluid distribution plenum 5204 behind the cages 806 and POMs and the use of low profile cold plates 5202 promotes air flow around the cages 806 and POMs, through the faceplate of the box, without obstruction. For example, the height of each of the cold plates 5202 may be limited to 4 mm adjacent to each cage 806 and POM at the front end of the cage 806 (the rear portion can be higher without blocking air into the circuit pack). Here, the ramp only structure of the cold plates 5202 utilizes no transition angles, relevant to the manufacturing and brazing process in terms of less complexity, easier gap filling, etc.

The cold plates 5202 include elongate structures that protrude from the fluid distribution plenum 5204 adjacent to the cages 806 and POMs, with one elongate structure per cage 806 and POM. The elongate structures are secured to the fluid distribution plenum 5204 by a retention plate 5100 that traverses one end of each of the elongate structures and is secured to the fluid distribution plenum 5204 via screws 5102 or the like. When individual cages 806 are utilized, as opposed to ganged cages 806, each of the elongate structures may also be secured to the cages 806 via conventional clip assemblies 5104 or the like. The retention plate 5100 and clip assemblies 5104 serve to bias each of the cold plates 5202 into the associated POM surface when the POM is inserted into the associated cage 806. The configuration of the retention plate 5100 is described in greater detail, however the retention plate 5100 generally runs along the rear of the fluid distribution plenum 5204 and the cold plates 5202.

The fluid distribution plenum 5204 includes an inlet plenum 5204a and an outlet plenum 5204b integrated into a single structure including a body 5300 and an affixed, sealed lid 5302. The body 5300 and lid 5302 may be made of any suitable rigid material, such as a metallic or plastic material. The inlet tube 5210a is in fluid communication with the inlet plenum 5204a and the outlet tube 5210b is in fluid communication with the outlet plenum 5204b, forming a continuous fluid flow path from the inlet tube 5210a, through the inlet plenum 5204a, through each of the cold plates 5202 in parallel, through the outlet plenum 5204b, and to the outlet tube 5210b, forming a cooling fluid path with the cold plates 5202 disposed in parallel. Each of the cold plates 5202, of which any number may be used and associated with any number of cages 806 and POMS, whether individual or ganged, is fluidly coupled to the fluid distribution plenum 5204 via an inlet piston cylinder 5304a and an outlet piston cylinder 5304b, each of which is disposed within a corresponding inlet/outlet port 5306a,5306b of the fluid distribution plenum 5204. O-rings 5308 are provided around the piston cylinders 5304 to provide a sealing connection that allows relative translation of each of the cold plates 5202 with respect to the fluid distribution plenum 5204.

The piston arrangement of the present disclosure allows the cooling fluid to be circulated from the fluid distribution plenum 5204 through the cold plates 5202 in parallel, while the cold plates 5202 are biased into the contacted POMs in a height restricted fluid containment application. This parallel cold plate configuration means that the same degree of cooling can be provided to each POM, as the POMs are not cooled in series, which would result in the first cold plate 5202 providing the greatest degree of cooling and the last cold plate 5202 providing the smallest degree of cooling as the cooling fluid is heated along the series. In the parallel cold plate configuration, each cold plate 5202 receives the same cool liquid from the inlet tube 5210a and the inlet plenum 5204a in parallel and provides hot liquid to the outlet plenum 5204b for communication directly to the outlet tube 5210b.

Each cold plate 5202 includes a body 5400 (the elongate structure) that defines a fluid flow path 5402 from the inlet piston cylinder 5304a to the outlet piston cylinder 5304b. The fluid flow path 5402 may be linear, circuitous, and/or could consist of a channel or chamber interrupted by fin structures or the like, well known to those of ordinary skill in the art with respect to such cold plate structures. The body 5400 is sealingly enclosed by the cold plate lid 5312. The inlet piston cylinder 5304a and the outlet piston cylinder 5304b are attached to/through the body 5400. Each piston cylinder 5304a, 5304b includes an external circumferential O-ring groove 5404 in which one of the O-rings 5308 is disposed. It should be noted that the body 5400 of each cold plate 5202 may include a tapered, rounded, and/or ramped external pad 5110 that forms the cooling POM contact portion of the cold plate 5202 and assists in the insertion/removal of the associated POM into the associated cage with the external pad 5110 making contact with the surface of the POM. The body 5400 and cold plate lid 5312 may be made of any suitable rigid material, such as a metallic material.

The body 5400 of each cold plate 5202 may be tapered in (vertical) thickness, being thickest at the fluid distribution plenum end. This allows the height of the cold plates 5202 above the cages 806 and POMs to be minimized, promoting air flow around the cages 806 and POMs.

The retention plate 5100 defines slots 5120 that are sized to capture associated tabs 5122 provided at the rear end of the cold plates 5202. These slots 5120 may be oversized in relation to the tabs 5122 (at least vertically), such that the cold plates 5202 may be provided with a degree of movement with respect to the fluid distribution plenum 5204, cages 806, and POMs (at least vertically), with relative translation provided along the axis of each of the fluid connections of the piston mechanisms. The use of the rear retention plate 5100 further reduces the vertical footprint of the parallel flow liquid cooling distribution assembly 5200. The retention plate 5100 may include cutouts or narrowed regions 5101 that further reduce the vertical footprint of the parallel flow liquid cooling distribution assembly 5200.

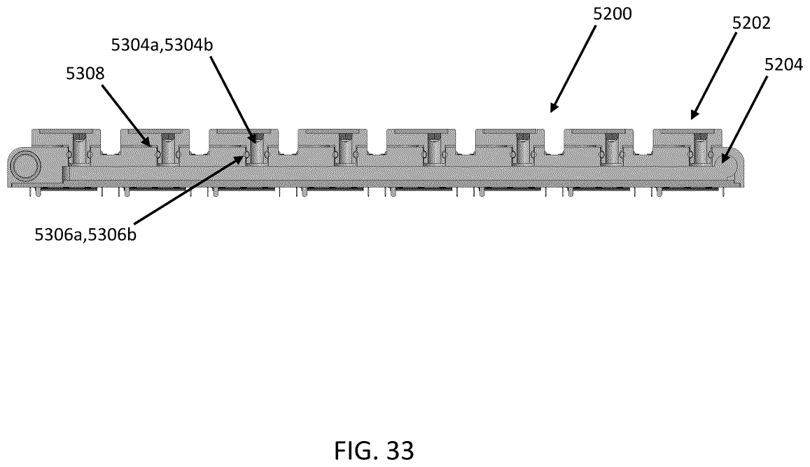

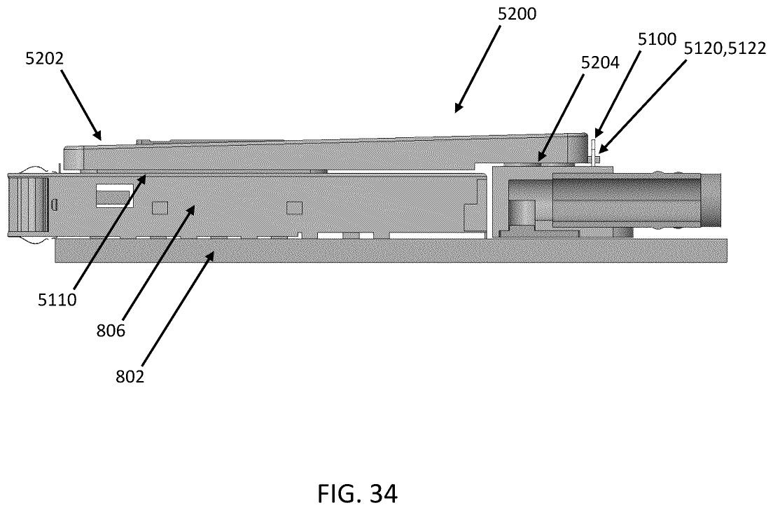

FIGS. 33 and 34 further illustrate the parallel flow liquid cooling distribution assembly 5200 of FIGS. 29-32. Again, each of the cold plates 5202, of which any number may be used and associated with any number of cages 806 and POMS, is fluidly coupled to the fluid distribution plenum 5204 via the inlet piston cylinder 5304a and the outlet piston cylinder 5304b, each of which is disposed within the corresponding port 5306a,5306b of the fluid distribution plenum 5204. The O-rings 5308 are provided around the piston cylinders 5304 to provide the sealing connection that allows relative translation of each of the cold plates 5202 with respect to the fluid distribution plenum 5204. Securement is accomplished via the retention plate 5100 that traverses the rear of the fluid distribution plenum 5204 and one end of each of the cold plates 5202 is secured to the fluid distribution plenum 5204 via the screws 5102 or the like. The external pad 5110 makes contact with the surface of the associated POM through the associated cage 806.

The retention plate 5100 defines slots 5120 that are sized to capture associated tabs 5122 provided at the rear end of the cold plates 5202. These slots 5120 may be oversized in relation to the tabs 5122 (at least vertically), such that the cold plates 5202 may be provided with a degree of movement with respect to the fluid distribution plenum 5204, cages, and POMs (at least vertically), with relative translation provided along the axis of each of the fluid connections of the piston mechanisms. The use of the rear retention plate 5100 further reduces the vertical footprint of the parallel flow liquid cooling distribution assembly 5200. It should be noted that, to maximize air flow, the cutouts 5101 are aligned with the spaces between the cold plates 5202.

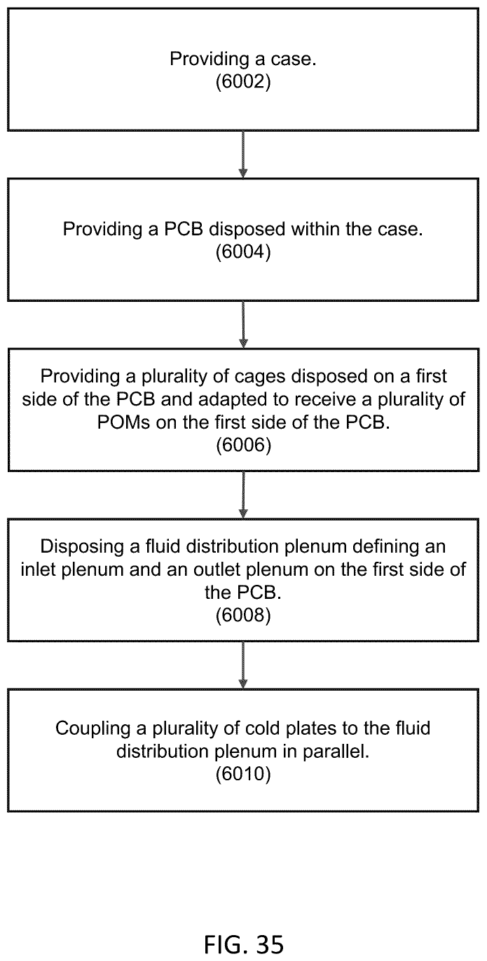

FIG. 35 illustrates an embodiment of the parallel flow liquid cooling distribution method 6000 of the present disclosure. The method 6000 includes providing a case (step 6002), providing a PCB disposed within the case (step 6004), and providing a plurality of cages disposed on a first side of the PCB and adapted to receive a plurality of POMs on the first side of the PCB (step 6006). The method 6000 further includes disposing a fluid distribution plenum defining an inlet plenum and an outlet plenum on the first side of the PCB (step 6008). The method 6000 further includes coupling a plurality of cold plates to the fluid distribution plenum in parallel, where each of the plurality of cold plates defines a fluid flow path and includes an inlet piston cylinder adapted to be sealingly disposed within an inlet port of the inlet plenum utilizing an intervening O-ring and an outlet piston cylinder adapted to be sealingly disposed within an outlet port of the outlet plenum utilizing an intervening O-ring, and where each of the plurality of cold plates is positioned to be disposed adjacent to and in contact with a surface of an associated POM through an associated cage of the plurality of cages and POMs disposed on the first side of the PCB (step 6010). In some embodiments, the method further includes repeating these same steps on a second side of the PCB.

Although the present disclosure is illustrated and described with reference to specific embodiments and examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A parallel flow liquid cooling distribution assembly for use in a telecommunications or optical networking system, the assembly comprising:
a fluid distribution plenum defining an inlet plenum and an outlet plenum; and
a plurality of cold plates coupled to the fluid distribution plenum in parallel, wherein each of the plurality of cold plates defines a fluid flow path and comprises an inlet piston cylinder adapted to be sealingly disposed within an inlet port of the inlet plenum and an outlet piston cylinder adapted to be sealingly disposed within an outlet port of the outlet plenum, and wherein each of the plurality of cold plates is positioned to be disposed adjacent to and in contact with a surface of an associated pluggable optical module through an associated cage of a plurality of cages and pluggable optical modules.

2. The assembly of claim 1, wherein the inlet piston cylinder is adapted to be sealingly disposed within the inlet port of the inlet plenum utilizing an intervening O-ring and the outlet piston cylinder is adapted to be sealingly disposed within the outlet port of the outlet plenum utilizing an intervening O-ring, and wherein the O-rings are each retained within a groove formed in one or both of the inlet piston cylinder or the outlet piston cylinder and the inlet port or the outlet port.

3. The assembly of claim 1, wherein the fluid distribution plenum is disposed above or below the plurality of cages and pluggable optical modules, with the plurality of cold plates disposed between the fluid distribution plenum and the plurality of cages and pluggable optical modules.

4. The assembly of claim 3, further comprising a spring disposed between each of the cold plates and the fluid distribution plenum, wherein the spring is adapted to bias each of the cold plates away from the fluid distribution plenum and into the surface of the associated pluggable optical module.

5. The assembly of claim 3, wherein each of the cold plates is disposed partially within an associated conformal recess formed in the fluid distribution plenum.

6. The assembly of claim 5, wherein the fluid distribution plenum comprises a retention plate that is disposed about the plurality of cold plates and coupled to the fluid distribution plenum to retain a lip structure of each of the cold plates within the associated conformal recess to couple the plurality of cold plates to the fluid distribution plenum such that each of the plurality of cold plates may be translated or biased towards or away from the fluid distribution plenum.

7. The assembly of claim 1, wherein the fluid distribution plenum is disposed behind the plurality of cages and pluggable optical modules, with the plurality of cold plates extending from the fluid distribution plenum to be disposed adjacent to plurality of cages and pluggable optical modules.

8. The assembly of claim 1, wherein the inlet piston cylinder and the outlet piston cylinder are disposed at an end of each of the cold plates.

9. The assembly of claim 7, further comprising a retention member that traverses the end of each of the cold plates and is secured to the fluid distribution plenum to secure the plurality of cold plates to the fluid distribution plenum.

10. The assembly of claim 7, further comprising a clip member that traverses each of the cold plates and is secured to the associated cage to bias each of the cold plates into the surface of the associated pluggable optical module.

11. The assembly of claim 7, further comprising a retention plate that is disposed along the end of each of the cold plates and is secured to the fluid distribution plenum to secure the plurality of cold plates to the fluid distribution plenum, wherein the retention plate defines a plurality of slots adapted to receive associated tabs provided at the ends of the cold plates.

12. The assembly of claim 11, wherein each of the plurality of slots has a height that is larger than a height of the associated tab, such that each of the plurality of cold plates is provided with a degree to translation with respect to the fluid distribution plenum.

13. The assembly of claim 11, wherein the retention plate defines a plurality of cutouts between adjacent cold plates of the plurality of cold plates that allow air flow past the plurality of cages and pluggable optical modules and the fluid distribution plenum.

14. The assembly of claim 7, wherein each of the cold plates comprises a body having a first planar portion proximate to the fluid distribution plenum, a second planar portion distal to the fluid distribution plenum, and a ramped transition portion disposed between the first planar portion and the second planar portion.

15. The assembly of claim 7, wherein each of the cold plates has a tapering thickness, being relatively thicker in height proximate to the fluid distribution plenum and relatively thinner in height distal to the fluid distribution plenum.

16. The assembly of claim 7, wherein each of the cold plates comprises an external pad adapted to make contact with the surface of the associated pluggable optical module through the associated cage.

17. A telecommunications or optical networking box assembly, comprising:
a case;
a printed circuit board disposed within the case;
a plurality of cages disposed on a first side of the printed circuit board and adapted to receive a plurality of pluggable optical modules on the first side of the printed circuit board;
a fluid distribution plenum defining an inlet plenum and an outlet plenum disposed on the first side of the printed circuit board; and
a plurality of cold plates coupled to the fluid distribution plenum in parallel, wherein each of the plurality of cold plates defines a fluid flow path and comprises an inlet piston cylinder adapted to be sealingly disposed within an inlet port of the inlet plenum and an outlet piston cylinder adapted to be sealingly disposed within an outlet port of the outlet plenum, and wherein each of the plurality of cold plates is positioned to be disposed adjacent to and in contact with a surface of an associated pluggable optical module through an associated cage of the plurality of cages and pluggable optical modules disposed on the first side of the printed circuit board.

18. The assembly of claim 17, further comprising:
a plurality of cages disposed on a second side of the printed circuit board and adapted to receive a plurality of pluggable optical modules on the second side of the printed circuit board;
a fluid distribution plenum defining an inlet plenum and an outlet plenum disposed on the second side of the printed circuit board; and
a plurality of cold plates coupled to the fluid distribution plenum in parallel, wherein each of the plurality of cold plates defines a fluid flow path and comprises an inlet piston cylinder adapted to be sealingly disposed within an inlet port of the inlet plenum and an outlet piston cylinder adapted to be sealingly disposed within an outlet port of the outlet plenum, and wherein each of the plurality of cold plates is positioned to be disposed adjacent to and in contact with a surface of an associated pluggable optical module through an associated cage of the plurality of cages and pluggable optical modules disposed on the second side of the printed circuit board.

19. A telecommunications or optical networking method, comprising:
providing a case;
providing a printed circuit board disposed within the case;
providing a plurality of cages disposed on a first side of the printed circuit board and adapted to receive a plurality of pluggable optical modules on the first side of the printed circuit board;
disposing a fluid distribution plenum defining an inlet plenum and an outlet plenum on the first side of the printed circuit board; and
coupling a plurality of cold plates to the fluid distribution plenum in parallel, wherein each of the plurality of cold plates defines a fluid flow path and comprises an inlet piston cylinder adapted to be sealingly disposed within an inlet port of the inlet plenum and an outlet piston cylinder adapted to be sealingly disposed within an outlet port of the outlet plenum, and wherein each of the plurality of cold plates is positioned to be disposed adjacent to and in contact with a surface of an associated pluggable optical module through an associated cage of the plurality of cages and pluggable optical modules disposed on the first side of the printed circuit board.

20. The method of claim 19, further comprising:
providing a plurality of cages disposed on a second side of the printed circuit board and adapted to receive a plurality of pluggable optical modules on the second side of the printed circuit board;
disposing a fluid distribution plenum defining an inlet plenum and an outlet plenum on the second side of the printed circuit board; and
coupling a plurality of cold plates to the fluid distribution plenum in parallel, wherein each of the plurality of cold plates defines a fluid flow path and comprises an inlet piston cylinder adapted to be sealingly disposed within an inlet port of the inlet plenum and an outlet piston cylinder adapted to be sealingly disposed within an outlet port of the outlet plenum, and wherein each of the plurality of cold plates is positioned to be disposed adjacent to and in contact with a surface of an associated pluggable optical module through an associated cage of the plurality of cages and pluggable optical modules disposed on the second side of the printed circuit board.
